(19) United States
(12) Patent Application Publication
(10) Pub. No.: US 2025/0155812 A1
(43) Pub. Date: May 15, 2025

(54) PHOTOSENSITIVE RESIN COMPOSITION, PHOTOSENSITIVE RESIN FILM, PHOTOSENSITIVE DRY FILM, AND PATTERN-FORMING PROCESS

(71) Applicant: SHIN-ETSU CHEMICAL CO., LTD., Tokyo (JP)

(72) Inventor: Hitoshi MARUYAMA, Annaka-shi (JP)

(73) Assignee: SHIN-ETSU CHEMICAL CO., LTD., Tokyo (JP)

(21) Appl. No.: 18/936,492

(22) Filed: Nov. 4, 2024

(30) Foreign Application Priority Data
Nov. 13, 2023 (JP) 2023-192850

(51) Int. Cl. G03F 7/075; G03F 7/004

(52) U.S. Cl. CPC G03F 7/0757; G03F 7/0045; G03F 7/0048; G03F 7/0751

(57) ABSTRACT

The present invention is a photosensitive resin composition including, (A) an acid-crosslinkable group-containing silicone resin, (B) an oxazoline compound or a derivative thereof, and (C) a photo-acid generator. This provides: a photosensitive resin composition that can easily form a thick and fine pattern without causing discoloration of copper and can form a resin film that is excellent in copper migration resistance, adhesiveness to a base material, and reliability; a photosensitive resin film; a photosensitive dry film; and a pattern-forming process by using these.

### TECHNICAL FIELD

The present invention relates to a photosensitive resin composition, a photosensitive resin film, a photosensitive dry film, and a pattern-forming process.

### BACKGROUND ART

Conventionally, a photosensitive protective film for a semiconductor device and a photosensitive insulating film for a multilayer printed circuit board are formed of a photosensitive polyimide composition, a photosensitive epoxy resin composition, a photosensitive silicone composition, etc. As such a photosensitive material applied for the protection of such a substrate and a circuit, Patent Document 1 proposes a photosensitive silicone composition having particularly excellent flexibility among them. This photosensitive silicone composition is curable at low temperature and can form a film that is excellent in reliability such as moisture-resistant adhesiveness, but has a problem of less resistance against chemicals such as a photoresist stripper having a high dissolving power like N-methyl-2-pyrrolidone.

To overcome the problem, Patent Document 2 proposes a photosensitive silicone composition based on a silphenylene structure-containing silicone polymer. Although the photosensitive silicone composition is improved in chemical resistance against photoresist strippers, etc., but further improvements are desired in light of the level of miniaturization achieved by pattern forming and resistance to copper migration. In addition, when the photosensitive silicone composition is used to form a pattern on copper, discoloration due to copper corrosion has been observed, and improvements are also desired in this regard.

### CITATION LIST

### Patent Literature

Patent Document 1: JP 2002-88158 A
Patent Document 2: JP 2008-184571 A

### SUMMARY OF INVENTION

### Technical Problem

The present invention has been made in view of the above-described problem. An object of the present invention is to provide: a photosensitive resin composition that can easily form a thick and fine pattern without causing discoloration of copper and can form a resin film (resin layer) that is excellent in copper migration resistance, adhesiveness to a base material, and reliability as a film for protecting an electric and electronic part, a substrate-bonding film, etc.; a photosensitive resin film; a photosensitive dry film; and a pattern-forming process by using these.

### Solution to Problem

To achieve the object, the present invention provides a photosensitive resin composition comprising:
(A) an acid-crosslinkable group-containing silicone resin;
(B) an oxazoline compound or a derivative thereof; and
(C) a photo-acid generator.

Such a photosensitive resin composition of the present invention can easily form a thick and fine pattern without causing discoloration of copper and can form a resin film (resin layer) that is excellent in copper migration resistance, adhesiveness to a base material, and reliability as a film for protecting an electric and electronic part, a substrate-bonding film, etc.

In this event, (A) the silicone resin is preferably represented by the following formula (A1),

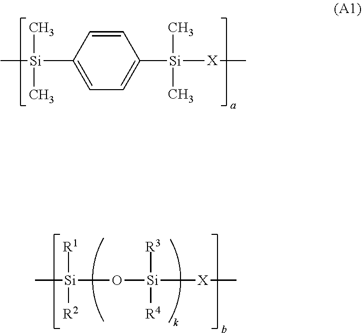

wherein R¹ to R⁴ each independently represent a hydrocarbyl group having 1 to 8 carbon atoms; “k” represents an integer of 1 to 600; “a” and “b” represent a composition ratio by mole of respective repeating units and represent numbers satisfying 0<a<1, 0<b<1, and a+b=1; and X represents a divalent organic group containing an epoxy group and/or a phenolic hydroxy group.

Such a component (A) can form a suitable resin film. Further, the obtained resin film has good adhesiveness to a laminate body, a substrate, etc., good pattern-formability, crack resistance, and heat resistance.

Further, (A) the silicone resin preferably comprises repeating units represented by the following formulae (a1) to (a4) and (b1) to (b4).

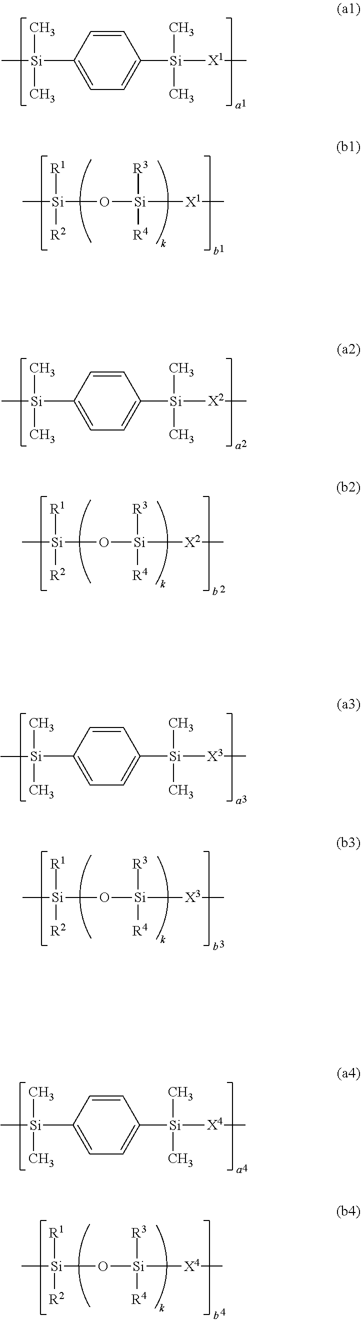

In the above formulae, R¹ to R⁴ each independently represent a hydrocarbyl group having 1 to 8 carbon atoms; “k” represents an integer of 1 to 600; a¹ to a⁴ and b¹ to b⁴ represent a composition ratio by mole of respective repeating units and represent numbers satisfying 0≤a¹<1, 0≤a²<1, 0≤a³<1, 0≤a⁴<1, 0≤b¹<1, 0≤b²<1, 0≤b³<1, 0≤b⁴<1, 0<a¹+a²+a³<1, 0<b¹+b²+b³<1, and a¹+a²+a³+a⁴+b¹+b²+b³+b⁴=1; X¹ represents a divalent organic group represented by the following formula (X1); X² represents a divalent organic group represented by the following formula (X2); X³ represents a divalent organic group represented by the following formula (X3); and X⁴ represents a divalent organic group represented by the following formula (X4).

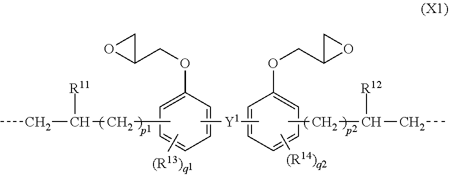

In the above formula, Y¹ represents a single bond, a methylene group, a propane-2,2-diyl group, a 1,1,1,3,3,3-hexafluoropropane-2,2-diyl group, or a fluorene-9,9-diyl group; R¹¹ and R¹² each independently represent a hydrogen atom or a methyl group; R¹³ and R¹⁴ each independently represent a saturated hydrocarbyl group having 1 to 4 carbon atoms or a saturated hydrocarbyloxy group having 1 to 4 carbon atoms; p¹ and p² each independently represent an integer of 0 to 7; q¹ and q² each independently represent an integer of 0 to 2; and a dashed line represents a bond.

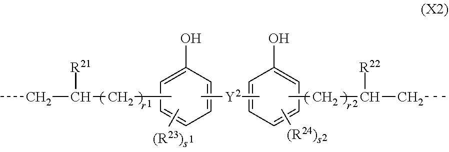

In the above formula, Y² represents a single bond, a methylene group, a propane-2,2-diyl group, a 1,1,1,3,3,3-hexafluoropropane-2,2-diyl group, or a fluorene-9,9-diyl group; R²¹ and R²² each independently represent a hydrogen atom or a methyl group; R²³ and R²⁴ each independently represent a saturated hydrocarbyl group having 1 to 4 carbon atoms or a saturated hydrocarbyloxy group having 1 to 4 carbon atoms; r¹ and r² each independently represent an integer of 0 to 7; s¹ and s² each independently represent an integer of 0 to 2; and a dashed line represents a bond.

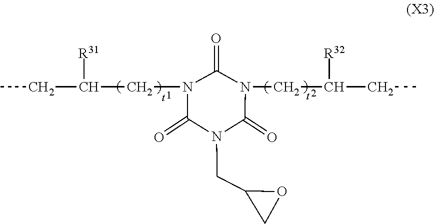

In the above formula, R³¹ and R³² each independently represent a hydrogen atom or a methyl group; t¹ and t² each independently represent an integer of 0 to 7; and a dashed line represents a bond.

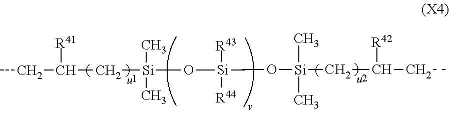

In the above formula, R⁴¹ and R⁴² each independently represent a hydrogen atom or a methyl group; R⁴³ and R⁴⁴ each independently represent a hydrocarbyl group having 1 to 8 carbon atoms; u¹ and u² each independently represent an integer of 0 to 7; “v” represents an integer of 0 to 600; and a dashed line represents a bond.

Such a component (A) can form a more suitable resin film. Further, a combination of the above repeating units can form a resin film having desired characteristics.

Furthermore, the photosensitive resin composition preferably includes (D) a crosslinker further.

In this event, (D) the crosslinker is preferably at least one compound selected from the group consisting of: a nitrogen-containing compound selected from the group consisting of melamine compounds, guanamine compounds, glycoluril compounds and urea compounds, having 2 or more methylol and/or alkoxymethyl groups on average in one molecule; an amino condensate modified with formaldehyde or formaldehyde-alcohol; a phenol compound having 2 or more methylol or alkoxymethyl groups on average in one molecule; and an epoxy compound having two or more epoxy groups on average in one molecule.

Such a component (D) can make it easy to form a pattern and can enhance a strength of the cured material.

The photosensitive resin composition includes (E) a solvent further.

Including such a component (E) can improve workability by suitable adjusting viscosity of the composition.

Further, the present invention provides a photosensitive resin film obtained from the photosensitive resin composition.

The inventive photosensitive resin film can provide a thick and fine pattern without causing discoloration of copper and is excellent in copper migration resistance, adhesiveness to a base material, and has a high reliability as a film for protecting an electric and electronic part and a substrate-bonding film.

Further, the present invention provides a photosensitive dry film including a support film and the photosensitive resin film on the support film.

The inventive photosensitive dry film is solid, and the photosensitive resin film does not contain a solvent. Accordingly, a bubble due to volatilization of the solvent will not remain in the photosensitive resin film and between the film and a substrate having asperities on its surface. Additionally, when the photosensitive dry film is adhered closely to a substrate having asperities on its surface, the photosensitive resin film fits in and covers the asperities to achieve high flatness. Particularly, the photosensitive resin film has lower viscoelasticity so that higher planarization can be achieved.

Further, the present invention provides a pattern-forming process including:
(i) forming a photosensitive resin film on a substrate using the photosensitive resin composition;
(ii) exposing the photosensitive resin film; and
(iii) developing the exposed photosensitive resin film with a developer to form a pattern.

Further, the present invention provides a pattern-forming process including:
(i′) forming a photosensitive resin film on a substrate by using the photosensitive dry film;
(ii) exposing the photosensitive resin film; and
(iii) developing the exposed photosensitive resin film with a developer to form a pattern.

The inventive pattern-forming process can easily form a thick and fine pattern without causing discoloration of copper and can efficiently form a resin film that is excellent in reliability as a film for protecting an electric and electronic part, a substrate-bonding film, etc.

In the present invention, the pattern-forming process preferably further include (iv) post-curing the photosensitive resin film patterned by the development at a temperature of 100° C. to 250° C.

This increases crosslinking density of the photosensitive resin composition and can remove remaining volatile components, and thus it is preferable in terms of adhesiveness to a substrate, heat resistance, strength, electric properties, and adhesive strength.

Further, in the present invention, the photosensitive resin composition is preferably a material to form a film for protecting an electric and electronic part and is preferably a material to form substrate-bonding film for bonding two substrates also.

The inventive photosensitive resin composition is useful as such a material.

### Advantageous Effects of Invention

The inventive photosensitive resin composition can form a film having a wide range of thickness, and can form a thick and fine pattern having excellent perpendicularity without causing discoloration of copper by the pattern-forming process described later. The film obtained from the inventive photosensitive resin composition and the inventive photosensitive dry film is excellent in adhesiveness to a substrate, an electronic part, a semiconductor device, etc., especially to a base material used for a circuit board, mechanical properties, electric insulation, copper migration resistance, and chemical resistance. Also, the film is highly reliable as an insulating protective film and suitably used as a material to form various films for protecting an electric and electronic part such as a circuit board, a semiconductor device, and a display device and a material to form a substrate-bonding film.

### DESCRIPTION OF EMBODIMENTS

As a result of diligent study to achieve the above objectives, the inventor found that the above objectives can be accomplished by a photosensitive resin composition including (A) an acid-crosslinkable group-containing silicone resin, (B) an oxazoline compound or a derivative thereof, and (C) a photo-acid generator and has completed the present invention.

Specifically, the present invention is a photosensitive resin composition including:
(A) an acid-crosslinkable group-containing silicone resin;
(B) an oxazoline compound or a derivative thereof; and
(C) a photo-acid generator.

The inventive photosensitive resin composition can easily form a thick and fine pattern without causing discoloration of copper, can form a resin film (resin layer) that is excellent in various film properties such as copper migration resistance and adhesiveness to a substrate, an electronic part, a semiconductor device, etc., especially to a base material used for a circuit board, and is excellent in reliability as a film for protecting an electric and electronic part, a substrate-bonding film, etc. This photosensitive resin composition can provide a photosensitive resin film, a photosensitive dry film, and a pattern-forming process using these.

Hereinafter, the present invention will be described in detail. However, the present invention is not limited thereto.

### [Photosensitive Resin Composition]

A photosensitive resin composition of the present invention contains (A) an acid-crosslinkable group-containing silicone resin, (B) an oxazoline compound, and (C) a photo-acid generator. As necessary, the inventive photosensitive resin composition may further contain other components than these, for example, such as (D) a crosslinker, (E) a solvent, and other additives.

Hereinafter, each component will be described.

### [(A) Acid-Crosslinkable Group-Containing Silicone Resin]

The component (A) acid-crosslinkable group-containing silicone resin contains an acid-crosslinkable group in the molecule. Here, the acid-crosslinkable group refers to a group in which functional groups can be chemically bonded to each other directly or via a crosslinker by the action of an acid. The acid-crosslinkable group is preferably an epoxy group or a phenolic hydroxy group. Only one of the epoxy group and the phenolic hydroxy group may be contained, or both of them may be contained.

The acid-crosslinkable group-containing silicone resin is preferably represented by the following formula (A1).

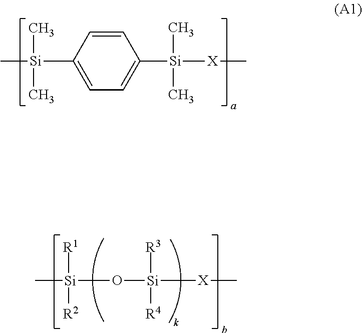

In formula (A1), R¹ to R⁴ each independently represent a hydrocarbyl group having 1 to 8 carbon atoms, preferably 1 to 6 carbon atoms; “k” represents an integer of 1 to 600, preferably 1 to 400, more preferably 1 to 200; “a” and “b” represent a composition ratio by mole of respective repeating units and are numbers satisfying 0<a<1, 0<b<1, and a+b=1; and X represents a divalent organic group containing an epoxy group and/or a phenolic hydroxy group.

The hydrocarbyl group may be linear, branched or cyclic. Specific examples thereof include: alkyl groups such as a methyl group, an ethyl group, a propyl group, a hexyl group, and structural isomers thereof; cyclic saturated hydrocarbyl groups such as a cyclohexyl group; and aryl groups such as a phenyl group. Among these, a methyl group and a phenyl group are preferable because they are readily available materials.

The silicone resin represented by the formula (A1) contain particularly preferably repeating units represented by the formulae (a1) to (a4) and (b1) to (b4). Hereinafter these units are also referred to as repeating units (a1) to (a4) and (b1) to (b4).

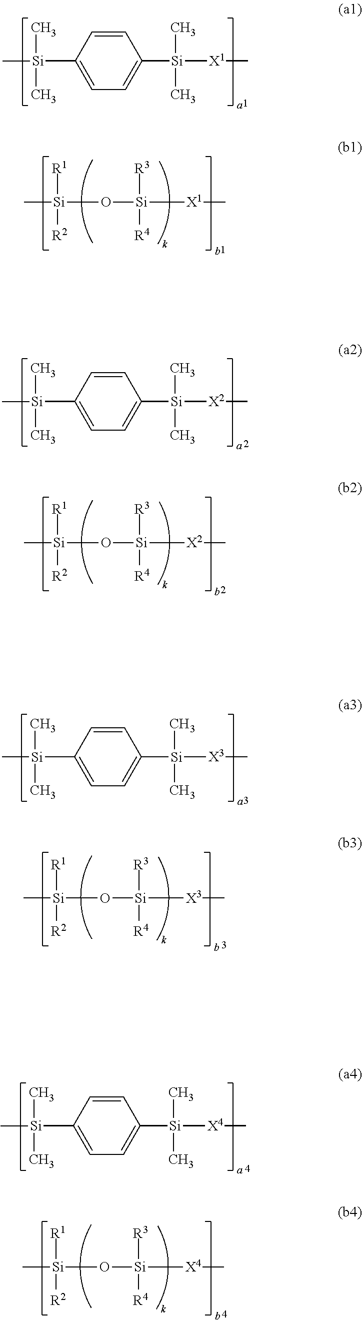

In the above formulae, R¹ to R⁴ and “k” are same as defined above.

In formulae (a1) and (b1), X¹ represents a divalent group represented by the following formula (X1).

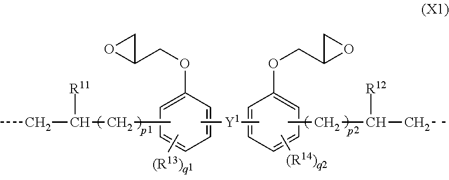

In the formula, the dashed line represents a bond.

In formula (X1), Y¹ represents a single bond, a methylene group, a propane-2,2-diyl group, a 1,1,1,3,3,3-hexafluoropropane-2,2-diyl group, or a fluorene-9,9-diyl group; R¹¹ and R¹² each independently represent a hydrogen or a methyl group; R¹³ and R¹⁴ each independently represent a saturated hydrocarbyl group having 1 to 4 carbon atoms or a saturated hydrocarbyloxy group having 1 to 4 carbon atoms; p¹ and p² each independently represent an integer of 0 to 7; q1 and q2 each independently represent an integer of 0 to 2.

The saturated hydrocarbyl group may be linear, branched, or cyclic. Specific examples thereof include: alkyl groups such as a methyl group, an ethyl group, a propyl group, a butyl group, and structural isomers thereof; and cyclic saturated hydrocarbyl groups such as a cyclopropyl group and a cyclobutyl group. The saturated hydrocarbyloxy group may be linear, branched, or cyclic. Specific examples thereof include: alkoxy groups such as a methoxy group, an ethoxy group, a propoxy group, a butoxy group, and structural isomers thereof; and cyclic saturated hydrocarbyloxy groups such as a cyclopropyloxy group and a cyclobutyloxy group; etc.

In formulae (a2) and (b2), X² represents a divalent group represented by the following formula (X2).

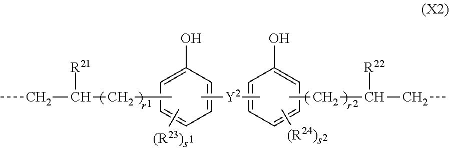

In the formula, the dashed line represents a bond.

In formula (X2), Y² represents a single bond, a methylene group, a propane-2,2-diyl group, a 1,1,1,3,3,3-hexafluoropropane-2,2-diyl group, or a fluorene-9,9-diyl group; R²¹ and R²² each independently represent a hydrogen or a methyl group; R²³ and R²⁴ represent each independently a saturated hydrocarbyl group having 1 to 4 carbon atoms or a saturated hydrocarbyloxy group having 1 to 4 carbon atoms; r¹ and r² each independently represent an integer of 0 to 7; s¹ and s² each independently represent an integer of 0 to 2. Examples of the saturated hydrocarbyl group and the saturated hydrocarbyloxy group include the same as those exemplified in the description about R¹³ and R¹⁴.

In the formulae (a3) and (b3), X³ represents a divalent group represented by the following formula (X3).

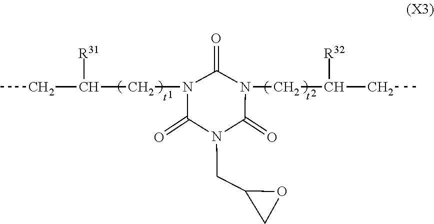

In the formula, the dashed line represents a bond.

In the formula (X3), R³¹ and R³² each independently represent a hydrogen or a methyl group; t¹ and t² each independently represent an integer of 0 to 7.

In the formulae (a4) and (b4), X⁴ represents a divalent group represented by the following formula (X4).

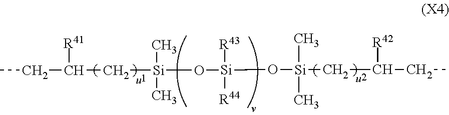

In the formula, the dashed line represents a bond.

In the formula (X4), R⁴¹ and R⁴² each independently represent a hydrogen atom or a methyl group; R⁴³ and R⁴⁴ each independently represent a hydrocarbyl group having 1 to 8 carbon atoms; u¹ and u² each independently represent an integer of 0 to 7; “v” represents an integer of 0 to 600, preferably an integer of 0 to 400, and more preferably an integer of 0 to 200. Examples of the hydrocarbyl group include the same as those exemplified in the description of R¹ to R⁴.

The component (A) silicone resin preferably has a weight-average molecular weight (Mw) of 3000 to 500000, more preferably 5000 to 200000. Note that, in the present invention, Mw is a value measured in terms of standard polyethylene by gel permeation chromatography (GPC) using tetrahydrofuran (THF) as a solvent.

In formulae (a1) to (a4) and (b1) to (b4), a¹ to a⁴ and b¹ to b⁴ represent a composition ratio by mole of respective repeating units and represent numbers satisfying 0≤a¹<1, 0≤a²<1, 0≤a³<1, 0≤a⁴<1, 0≤b¹<1, 0≤b²<1, 0≤b³<1, 0≤b⁴<1, 0<a¹+a²+a³<1, 0<b¹+b²+b³<1, and a¹+a²+a³+a⁴+b¹+b²+b³+b⁴=1; preferably, 0≤a¹≤0.8, 0≤a²≤0.8, 0≤a³≤0.8, 0≤a⁴≤0.8, 0≤b¹≤0.95, 0≤b²≤0.95, 0≤b³<0.95, 0≤b⁴≤0.95, 0.05≤a¹+a²+a³<0.8, 0.2≤b¹+b²+b³<0.95, and a¹+a²+a³+a⁴+b¹+b²+b³+b⁴=1; further preferably, 0≤a¹≤0.7, 0≤a²≤0.7, 0.1<a³<0.7, 0≤a⁴<0.7, 0≤b¹<0.9, 0≤b²≤0.9, 0≤b³≤0.9, 0≤b⁴≤0.9, 0.1≤a¹+a²+a³<0.7, 0.3≤b¹+b²+b³≤0.9, and a¹+a²+a³+a⁴+b¹+b²+b³+b⁴=1. Furthermore, from the viewpoint of reaction, 0<b²<1 is preferable, 0.2≤b²≤0.95 is more preferable, and 0.3≤b²<0.9 is further preferable.

The above-mentioned repeating units may be bonded randomly or bonded as a block polymer. When each repeating unit includes two or more siloxane units, the siloxane units may be all the same or may include two or more different types. When siloxane units include two or more different types, siloxane units may be randomly bonded or include a plurality of blocks each consisting of siloxane units of the same type. The silicone resin preferably has a silicone (siloxane unit) content of 30 to 80 mass %.

The component (A) silicone resin functions to impart a film-forming ability. The obtained resin film has good adhesiveness to a laminate body, a substrate, etc., a good pattern-formability, crack resistance, and heat resistance.

One kind of the component (A) silicone resin may be used alone, or two or more kinds thereof may be used in combination.

### [Preparation of (A) Silicone Resin]

The component (A) silicone resin may be prepared by a hydrosilylated reaction using an organic silicon compound having an acid-crosslinkable group as a material. The organic silicon compound as a material may be selected appropriately depending on the desired acid-crosslinkable group-containing silicone resin. When the component (A) is a silicone resin represented by the formula (A1), for example, it is possible to produce the silicone resin by addition polymerizing of: a compound represented by the following formula (1); a compound represented by the following formula (2); at least one compound selected from the group consisting of a compound represented by the following formula (3), a compound represented by the following formula (4), and a compound represented by the following formula (5); and optionally a compound represented by the following formula (6) as necessary, in the presence of a metal catalyst.

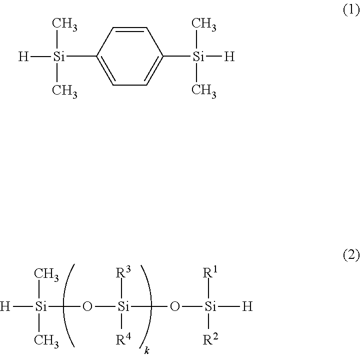

In the above formulae, R¹ to R⁴ and “k” are same as defined above.

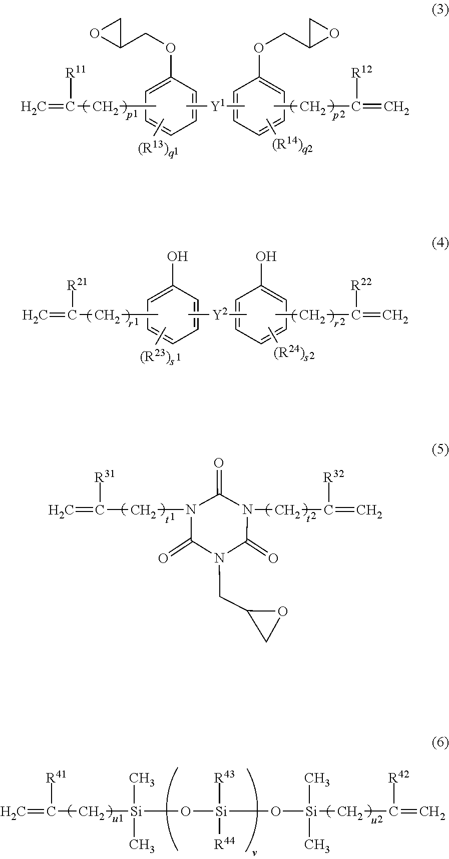

In the formulae above, R¹¹ to R¹⁴, R²¹ to R²⁴, R³¹, R³², R⁴¹ to R⁴⁴, Y¹, Y², p¹, p², q¹, q², r¹, r², s¹, s², t¹, t², u¹, u² and “v” are same as above.

Examples of the metal catalyst include: platinum group metals alone such as platinum (including platinum black), rhodium, and palladium; platinum chlorides, chloroplatinic acids and chloroplatinates such as H₂PtCl₄·xH₂O, H₂PtCl₆·xH₂O, NaHPtCl₆·xH₂O, KHPtCl₆·xH₂O, Na₂PtCl₆·xH₂O, K₂PtCl₄·xH₂O, PtCl₄·xH₂O, PtCl₂, Na₂PtCl₄·xH₂O, wherein “x” is preferably an integer of 0 to 6, more preferably 0 or 6; alcohol-modified chloroplatinic acids, for example, as described in the specification of U.S. Pat. No. 3,220,972 A; chloroplatinic acid-olefin complexes, for example, as described in the specification of U.S. Pat. Nos. 3,159,601 A, 3,159,662 A, and 3,775,452 A; platinum group metals such as platinum black and palladium supported on a carrier such as alumina, silica, carbon, etc.; rhodium-olefin complexes; chlorotris(triphenylphosphine) rhodium known as Wilkinson's catalyst; and complexes of vinyl group-containing siloxanes, specifically vinyl group-containing cyclic siloxanes, with platinum chlorides, chloroplatinic acids, or chloroplatinates; etc.

In general, the catalyst is used in a catalytic amount, which is, preferably 0.001 to 0.1 part by mass, more preferably 0.01 to 0.1 part by mass relative to 100 parts by mass of total of the material compounds.

In the addition polymerization reaction, a solvent may be used if necessary. The solvents are preferably hydrocarbon solvents such as toluene and xylene.

The polymerization temperature is preferably 40 to 150° C., more preferably 60 to 120° C., from the perspective that the catalyst may not be deactivated and the polymerization can be completed within a short time. While the polymerization time varies with the type and amount of the resulting resin, it is preferably about 0.5 to 100 hours, more preferably about 0.5 to 30 hours for preventing moisture entry into the polymerization system. After completion of the reaction, the solvent if used is distilled off to be able to obtain the component (A) silicone resin.

The reaction process is not particularly limited. For example, in the case where a compound represented by the formula (1), a compound represented by the formula (2), and at least one compound selected from the group consisting of a compound represented by the formulae (3), (4), and (5), and optionally a compound represented by the formula (6) as necessary, are brought to the reaction, reaction process include the following: first, at least one compound selected from the group consisting of a compound represented by the formula (3), a compound represented by the formula (4), and a compound represented by the formula (5), and optionally the compound represented by formula (6) on a necessary base, are mixed; the mixture is heated; a metal catalyst is added to the mixture; and the compound represented by formula (1) and the compound represented by formula (2) are added to the mixture dropwise over 0.1 to 5 hours.

The compounds each are preferably blended in such amounts that a composition ratio by mole of the total hydrosilyl groups included in the compound represented by formula (1) and the compound represented by formula (2) relative to the total alkenyl groups included in the at least one compound selected from the compounds having formulae (3), (4), and (5), and the optional compound having formula (6) is preferably within a range from 0.67 to 1.67, more preferably within a range from 0.83 to 1.25.

The Mw of the obtained resin may be controlled by using a monoallyl compound such as o-allylphenol, monohydrosiloxane, or monohydrosilane such as triethylhydrosilane, as a molecular weight regulator.

### [(B) Oxazoline Compound or Derivative Thereof]

The component (B) oxazoline compound is a compound having a structure represented by the following formula (B1).

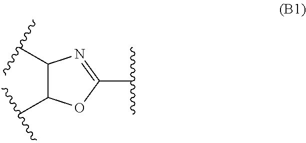 [SMILES: *C1=NC(*)C(*)O1]

The oxazoline compound is not particularly limited, and commercially available products can be used. Specific examples thereof include 2-amino-2-oxazoline, 2,2′-(1,3-phenylene)bis(2-oxazoline), 2,2′-(1,4-phenylene)bis(2-oxazoline), 2,2′-(2,6-pyridinediyl)bis(4-isopropyl-2-oxazoline), 2,2′-(4,6-m-xylylenediyl)bis(4-isopropyl-2-oxazoline), 2,2′-bis(2-oxazoline), 2,2′-(2,6-pyridinediyl)bis(4-phenyl-2-oxazoline), 4-tert-butyl-2-(2-pyridyl) oxazoline, 2-phenyl(2-oxazoline), 4,4-dimethyl-2-oxazoline, 2-ethyl-2-oxazoline, 2,2′-isopropylidenebis(4-tert-butyl-2-oxazoline), 2,2′-isopropylidenebis(4-isopropyl-2-oxazoline), 2,2′-isopropylidenebis(4-phenyl-2-oxazoline), 2-isopropyl-2-oxazoline, 2-methyl-2-oxazoline, 2,2′-(diethylmethylene)bis(4-benzyl-2-oxazoline), 5-phenylbenzoxazole-2-thiol, 2-propyl-2-oxazoline, 2,4,4-trimethyl-2-oxazoline, etc.

Among these, 2,2′-(1,3-phenylene)bis(2-oxazoline), 2,2′-(1,4-phenylene)bis(2-oxazoline), 2,2′-bis(2-oxazoline), 4,4-dimethyl-2-oxazoline, 2-ethyl-2-oxazoline, 2-methyl-2-oxazoline, 2-propyl-2-oxazoline, 2,4,4-trimethyl-2-oxazoline, 4-tert-butyl-2-(2-pyridyl) oxazoline, and 2,2′-isopropylidenebis(4-phenyl-2-oxazoline) are preferred.

By adding an oxazoline compound or a derivative thereof, a clear contrast of the amount of acid generated by the photo-acid generator is provided between the exposed and unexposed parts, improving the resolution, suppressing the change in sensitivity after exposure, reducing substrate-dependency or environment-dependency, and improving the exposure margin and pattern shape. In addition, a pattern can be formed without discoloration of copper. Furthermore, a good catalytic effect is exhibited during post-curing, and it is possible to obtain a cured film excellent in reliability and migration resistance.

Although such an effect is not bound by any particular theory, such an effect is speculated to be brought about by the fact that the oxazoline compound or a derivative thereof of the component (B) has both basicity that can appropriately control the migration of generated acid and can also exhibit a catalytic effect that enhances the reactivity of the acid-crosslinkable group by heating, and a coordinating ability that can suppress copper migration.

When the acid-crosslinkable group is an epoxy group, a basic compound or a salt thereof such as quaternary ammonium salts, tertiary amines and their salts, and imidazole compounds, which are known as a curing agent or a curing aid for epoxy resins, is considered to be blended from the viewpoint of improving curing properties. On the other hand, depending on its basicity (base strength), there is a risk that it may neutralize the acid generated from the photo-acid generator and reduce the reactivity of the acid-crosslinkable group.

In addition, nitrogen-containing heterocyclic compounds that can suppress the migration of copper ions are known to be: compounds having one nitrogen atom in the nitrogen-containing heterocycle such as piperidine and pyridine; compounds having two nitrogen atoms in the nitrogen-containing heterocycle such as imidazole, pyrazole, pyrazoline, pyrazolidine, pyrimidine, and pyridazine; compounds having three nitrogen atoms in the nitrogen-containing heterocycle such as 1,2,3-triazole, 1,2,4-triazole, and triazine; and compounds having four nitrogen atoms in the nitrogen-containing heterocycle such as 1H-tetrazole (JP 2012-181281 A). These nitrogen-containing heterocyclic compounds also have corresponding base strengths.

However, compositions that do not contain the component (B) to be combined with (A) an acid-crosslinkable group-containing silicone resin have poor resolution limit and shape in pattern forming; the migration and discoloration of copper cannot be suppressed; and the obtained pattern has poor reliability, adhesive strength, and solvent resistance. In particular, it is known that diaminotriazine compounds having an imidazole ring that are used as a curing agent or a curing accelerator for epoxy resins, suppress the discoloration of copper (see JPH07-33766 A), but the discoloration of copper cannot be suppressed and the characteristics of the pattern to be formed will be inferior even if such a compound are blended.

As described above, the present invention can exhibit advantageous effects that cannot be predicted from the prior art by combining (A) an acid-crosslinkable group-containing silicone resin and (B) an oxazoline compound or its derivative.

In addition, although it is known that a compound having an oxazoline skeleton can react with a carboxyl group in a polymer to be crosslinked (see JP 2009-003369 A), the present invention can exhibit the above-mentioned excellent effects, even if the component (A) or other component does not contain a carboxyl group in their structures.

The content of the component (B) is preferably 0.01 to 10 parts by mass, and more preferably 0.01 to 3 parts by mass, relative to 100 parts by mass of the component (A). When the content of the component (B) is 0.01 part by mass or more, a sufficient effect can be obtained. When the content is 10 parts by mass or less, compatibility with the component (A) is good and there is no risk of problems such as reduced transparency, which is preferable. One kind of the component (B) may be used alone or two or more kinds thereof may be used in combination.

### [(C) Photo-Acid Generator]

The photo-acid generator of the component (C) is not particularly limited as long as it decomposes when exposed to light and generates acid, but it is preferably one that decomposes and generates acid when exposed to light with a wavelength of 190 to 500 nm. The photo-acid generator serves as a curing catalyst. Because the inventive photosensitive resin composition has excellent compatibility with a photo-acid generator, a wide variety of photo-acid generators can be used.

Examples of the photo-acid generator include onium salts, diazomethane derivatives, glyoxime derivatives, β-ketosulfone derivatives, disulfone derivatives, nitrobenzylsulfonate derivatives, sulfonate ester derivatives, imid-yl-sulfonate derivatives, oximesulfonate derivatives, iminosulfonate derivatives, etc.

Examples of the onium salts include a sulfonium salt represented by the following formula (C1), an iodonium salt represented by the following formula (C2), or the like.

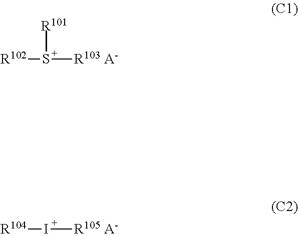

In the formulae (C1) and (C2), R¹⁰¹ to R¹⁰⁵ each independently represent a saturated hydrocarbyl group that has 1 to 12 carbon atoms and may have a substituent, an aryl group that has 6 to 12 carbon atoms and may have a substituent, or an aralkyl group that has 7 to 12 carbon atoms and may have a substituent. A-represents a non-nucleophilic counter ion.

The saturated hydrocarbyl group may be linear, branched, or cyclic, and specific examples thereof include: alkyl groups such as a methyl group, an ethyl group, a propyl group, a butyl group, a pentyl group, a hexyl group, and structural isomers thereof; and cyclic saturated hydrocarbyl groups such as a cyclopropyl group, a cyclobutyl group, a cyclopentyl group, a cyclohexyl group, a norbornyl group, and an adamantyl group. The aryl group includes a phenyl group, a naphthyl group, a and a biphenylyl group, etc. The aralkyl group includes a benzyl group, a phenethyl group, etc.

Examples of the substituents include an oxo group, a saturated hydrocarbyl group having 1 to 12 carbon atoms, a saturated hydrocarbyloxy group having 1 to 12 carbon atoms, an aryl group having 6 to 24 carbon atoms, an aralkyl group having 7 to 25 carbon atoms, an aryloxy group having 6 to 24 carbon atoms, an arylthio group having 6 to 24 carbon atoms, etc. The hydrocarbyl moiety of the saturated hydrocarbyl group and the saturated hydrocarbyloxy group may be linear, branched, or cyclic, and specific examples thereof include the same as those exemplified as saturated hydrocarbyl groups represented by R¹⁰¹ to R¹⁰⁵.

Preferable examples of R¹⁰¹ to R¹⁰⁵ include: saturated hydrocarbyl groups optionally having a substituent such as a methyl group, an ethyl group, a propyl group, a butyl group, a cyclohexyl group, a norbornyl group, an adamantyl group, and a 2-oxocyclohexyl group; aryl groups optionally having a substituent such as a phenyl group, a naphthyl group, a biphenylyl group, 2-, 3- or 4-methoxyphenyl group, 2-, 3- or 4-ethoxyphenyl group, 3- or 4-tert-butoxyphenyl group, 2-, 3- or 4-ethylphenyl group, 4-tert-butylphenyl group, a dimethylphenyl group, a terphenylyl group, a biphenylyloxyphenyl group, a biphenylylthiophenyl group; and aralkyl groups optionally having a substituent such as a benzyl group and a phenethyl group. Among these, aryl groups optionally having a substituent and aralkyl groups optionally having a substituent are more preferable.

Examples of the non-nucleophilic counter ion include: halide ion such as a chloride ion and a bromide ion; fluoroalkanesulfonate ions such as a triflate ion, a 1,1,1-trifluoroethanesulfonate ion, and a nonafluorobutanesulfonate ion; arylsulfonate ions such as a tosylate ion, a benzenesulfonate ion, a 4-fluorobenzenesulfonate ion, and a 1,2,3,4,5-pentafluorobenzenesulfonate ion; alkanesulfonate ions such as a mesylate ion and a butanesulfonate ion; fluoroalkanesulfone imide ions such as a trifluoromethanesulfone imide ion; fluoroalkanesulfonyl methide ions such as a tris(trifluoromethanesulfonyl)methide ion; borate ions such as a tetrakisphenylborate ion and a tetrakis(pentafluorophenyl)borate ion; phosphate ions such as a hexafluorophosphate ion, a tris(pentafluoroethyl)trifluorophosphate ion; etc.

Examples of the diazomethane derivatives include a compound represented by the following formula (C3).

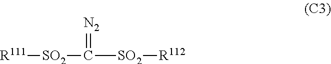

In the formula (C3), R¹¹¹ and R¹¹² each independently represent a saturated hydrocarbyl having 1 to 12 carbon atoms, or halogenated saturated hydrocarbyl having 1 to 12 carbon atoms, an aryl group having 6 to 12 carbon atoms or an aralkyl group having 7 to 12 carbon atoms which optionally have a substituent.

The saturated hydrocarbyl group may be linear, branched, or cyclic, and specific examples thereof include the same as those exemplified as the saturated hydrocarbyl groups represented by R¹⁰¹ to R¹⁰⁵. Examples of the halogenated saturated hydrocarbyl group include a trifluoromethyl group, a 1,1,1-trifluoroethyl group, a 1,1,1-trichloroethyl group, and a nonafluorobutyl group, etc.

Examples of the aryl group optionally having a substituent include: a phenyl group; alkoxyphenyl groups such as 2-, 3- or 4-methoxyphenyl group, 2-, 3- or 4-ethoxyphenyl group, and 3- or 4-tert-butoxyphenyl group; alkylphenyl groups such as a 2-, 3- or 4-methylphenyl group, a 2-, 3- or 4-ethylphenyl group, a 4-tert-butylphenyl group, a 4-butylphenyl group, and a dimethylphenyl group; halogenated aryl groups such as a fluorophenyl group, a chlorophenyl group, and a 1,2,3,4,5-pentafluorophenyl group; etc. Examples of the aralkyl group include a benzyl group, a phenethyl group, etc.

Specific examples of the onium salts include diphenyliodonium trifluoromethanesulfonate, (p-tert-butoxyphenyl)phenyliodonium trifluoromethanesulfonate, diphenyliodonium p-toluenesulfonate, (p-tert-butoxyphenyl)phenyliodonium p-toluenesulfonate, triphenylsulfonium trifluoromethanesulfonate, (p-tert-butoxyphenyl)diphenylsulfonium trifluoromethanesulfonate, bis(p-tert-butoxyphenyl)phenylsulfonium trifluoromethanesulfonate, tris(p-tert-butoxyphenyl) sulfonium trifluoromethanesulfonate, triphenylsulfonium p-toluenesulfonate, (p-tert-butoxyphenyl)diphenylsulfonium p-toluenesulfonate, bis(p-tert-butoxyphenyl)phenylsulfonium p-toluenesulfonate, tris(p-tert-butoxyphenyl) sulfonium p-toluenesulfonate, triphenylsulfonium nonafluorobutanesulfonate, triphenylsulfonium butanesulfonate, trimethylsulfonium trifluoromethanesulfonate, trimethylsulfonium p-toluenesulfonate, cyclohexylmethyl(2-oxocyclohexyl)sulfonium trifluoromethanesulfonate, cyclohexylmethyl(2-oxocyclohexyl) sulfonium p-toluenesulfonate, dimethylphenylsulfonium trifluoromethanesulfonate, dimethylphenylsulfonium p-toluenesulfonate, dicyclohexylphenylsulfonium trifluoromethanesulfonate, dicyclohexylphenylsulfonium p-toluenesulfonate, bis(4-tert-butylphenyl) iodonium hexafluorophosphate, 4-(phenylthio)phenyldiphenylsulfonium tris(pentafluoroethyl)trifluorophosphate, diphenyl(4-thiophenoxyphenyl)sulfonium hexafluoroantimonate, [4-(4-biphenylylthio)phenyl]-4-biphenylylphenylsulfonium tris(trifluoromethanesulfonyl)methide, triphenylsulfonium tetrakis(fluorophenyl)borate, tris[4-(4-acetylphenyl)thiophenyl]sulfonium tetrakis(fluorophenyl)borate, triphenylsulfonium tetrakis(pentafluorophenyl)borate, tris[4-(4-acetylphenyl)thiophenyl]sulfonium tetrakis(pentafluorophenyl)borate, etc.

Specific examples of the diazomethane derivatives include bis(benzenesulfonyl)diazomethane, bis(p-toluenesulfonyl)diazomethane, bis(xylenesulfonyl)diazomethane, bis(cyclohexylsulfonyl)diazomethane, bis(cyclopentylsulfonyl)diazomethane, bis(n-butylsulfonyl)diazomethane, bis(isobutylsulfonyl)diazomethane, bis(sec-butylsulfonyl)diazomethane, bis(n-propylsulfonyl)diazomethane, bis(isopropylsulfonyl)diazomethane, bis(tert-butylsulfonyl)diazomethane, bis(n-pentylsulfonyl)diazomethane, bis(isopentylsulfonyl)diazomethane, bis(sec-pentylsulfonyl)diazomethane, bis(tert-pentylsulfonyl)diazomethane, 1-cyclohexylsulfonyl-1-(tert-butylsulfonyl)diazomethane, 1-cyclohexylsulfonyl-1-(tert-pentylsulfonyl)diazomethane, 1-tert-pentylsulfonyl-1-(tert-butylsulfonyl)diazomethane, etc.

Specific examples of the glyoxime derivatives include bis-o-(p-toluenesulfonyl)-α-dimethylglyoxime, bis-o-(p-toluenesulfonyl)-α-diphenylglyoxime, bis-o-(p-toluenesulfonyl)-α-dicyclohexylglyoxime, bis-o-(p-toluenesulfonyl)-2,3-pentanedioneglyoxime, bis-(p-toluenesulfonyl)-2-methyl-3,4-pentanedioneglyoxime, bis-o-(n-butanesulfonyl)-α-dimethylglyoxime, bis-o-(n-butanesulfonyl)-α-diphenylglyoxime, bis-o-(n-butanesulfonyl)-α-dicyclohexylglyoxime, bis-o-(n-butanesulfonyl)-2,3-pentanedioneglyoxime, bis-o-(n-butanesulfonyl)-2-methyl-3,4-pentanedioneglyoxime, bis-o-(methanesulfonyl)-α-dimethylglyoxime, bis-o-(trifluoromethanesulfonyl)-α-dimethylglyoxime, bis-o-(1,1,1-trifluoroethanesulfonyl)-α-dimethylglyoxime, bis-o-(tert-butanesulfonyl)-α-dimethylglyoxime, bis-o-(perfluorooctanesulfonyl)-α-dimethylglyoxime, bis-o-(cyclohexanesulfonyl)-α-dimethylglyoxime, bis-o-(benzenesulfonyl)-α-dimethylglyoxime, bis-o-(p-fluorobenzenesulfonyl)-α-dimethylglyoxime, bis-o-(p-tert-butylbenzenesulfonyl)-α-dimethylglyoxime, bis-o-(xylenesulfonyl)-α-dimethylglyoxime, bis-o-(camphorsulfonyl)-α-dimethylglyoxime, etc.

Specific examples of the β-ketosulfone derivatives include 2-cyclohexylcarbonyl-2-(p-toluenesulfonyl) propane, 2-isopropylcarbonyl-2-(p-toluenesulfonyl) propane, etc.

Specific examples of the disulfone derivatives include diphenyldisulfone, dicyclohexyldisulfone, etc.

Specific examples of the nitrobenzylsulfonate derivatives include 2,6-dinitrobenzyl p-toluenesulfonate, 2,4-dinitrobenzyl p-toluenesulfonate, etc.

Specific examples of the sulfonate ester derivatives include 1,2,3-tris(methanesulfonyloxy)benzene, 1,2,3-tris(trifluoromethanesulfonyloxy)benzene, 1,2,3-tris(p-toluenesulfonyloxy)benzene, etc.

Specific examples of the imid-yl-sulfonate derivatives include phthalimid-yl-triflate, phthalimid-yl-tosylate, 5-norbornene-2,3-dicarboxyimid-yl-triflate, 5-norbornene-2,3-dicarboxyimid-yl-tosylate, 5-norbornene-2,3-dicarboxyimid-yl-n-butylsulfonate, n-trifluoromethylsulfonyloxynaphthylimide, etc.

Specific examples of the oximesulfonate derivatives include α-(benzenesulfonium oxyimino)-4-methylphenylacetonitrile, α-(p-tolylsulfoniumoximino)-p-methoxyphenylacetonitrile, etc.

Specific examples of the iminosulfonate derivatives include (5-(4-methylphenyl) sulfonyloxyimino-5H-thiophen-2-ylidene)-(2-methylphenyl) acetonitrile, (5-(4-(4-methylphenylsulfonyloxy)phenylsulfonyloxyimino)-5H-thiophen-2-ylidene)-(2-methylphenyl)-acetonitrile, etc.

Additionally, it is also possible to use suitably 2-methyl-2-[(4-methylphenyl) sulfonyl]-1-[(4-methylthio)phenyl]-1-propane, etc.

The component (C) is contained in an amount of preferably 0.05 to 20 parts by mass from the viewpoint of photo-curing, more preferably 0.05 to 5 parts by mass, relative to 100 parts by mass of the component (A). When the content of the component (C) is 0.05 parts by mass or more, sufficient acid is generated and the crosslinking reaction progresses sufficiently. When the content is 20 parts by mass or less, the photo-acid generator can suppress an increase in the absorbance itself, does not cause a problem of decreased transparency, and is preferable. One kind of the component (C) may be used alone, or two or more kinds thereof may be used in combination.

### [(D) Crosslinker]

The inventive photosensitive resin composition preferably further contains a crosslinker as a component (D). The crosslinker reacts with the acid-crosslinkable group in the component (A) or other crosslinkable group if present, to have a function to increase the degree of crosslinking of the cured product. For example, when the aforementioned component (A) has a phenolic hydroxy group or a saturated hydrocarbyloxy group represented by R¹³, R¹⁴, R²³, or R²⁴, it undergoes a condensation reaction with these, becoming a component that can easily form a pattern and further increasing the strength of the cured product. From this viewpoint, it is preferable that (D) the crosslinker is combined with an acid-crosslinkable group-containing silicone resin in which the component (A) has an acid-crosslinkable group represented by the formula (A1).

The crosslinker is at least one compound selected from the group consisting of: a nitrogen-containing compound selected from the group consisting of melamine compounds, guanamine compounds, glycoluril compounds, or urea compounds, having 2 or more methylol and/or alkoxymethyl groups on average in one molecule; an amino condensate modified with formaldehyde or formaldehyde-alcohol; a phenol compound having 2 or more methylol or alkoxymethyl groups on average in one molecule; and an epoxy compound having two or more epoxy groups on average in one molecule.

The melamine compounds include a compound represented by the following formula (D1).

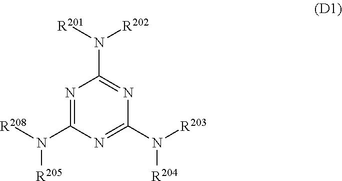

In the formula (D1), R²⁰¹ to R²⁰⁶ are each independently a methylol group, a saturated hydrocarbyloxymethyl group having 2 to 5 carbon atoms, or a hydrogen atom, and at least one of them is a methylol group or a saturated hydrocarbyloxymethyl group. Examples of the saturated hydrocarbyloxymethyl group include alkoxymethyl groups such as a methoxymethyl group and an ethoxymethyl group.

Examples of the melamine compound represented by the formula (D1) include trimethoxymethyl monomethylol melamine, dimethoxymethyl monomethylol melamine, trimethylol melamine, hexamethylol melamine, hexamethoxymethyl melamine, hexaethoxymethyl melamine, etc.

The melamine compound represented by formula (D1) can be obtained, for example, by first modifying a melamine monomer with formaldehyde through methylolation according to a known method, or by further modifying the melamine monomer with alcohol through alkoxylation. Note that, the alcohol is preferably a lower alcohol, for example, an alcohol having 1 to 4 carbon atoms.

Examples of the guanamine compound include tetramethylolguanamine, tetramethoxymethylguanamine, tetramethoxyethylguanamine, etc.

Examples of the glycoluril compounds include tetramethylol glycoluril and tetrakis(methoxymethyl)glycoluril, etc.

Examples of the urea compound include tetramethylol urea, tetramethoxymethyl urea, tetramethoxyethyl urea, tetraethoxymethyl urea, tetrapropoxymethyl urea, etc.

Examples of the amino condensate modified with the formaldehyde or the formaldehyde-alcohol include a melamine condensate modified with formaldehyde or formaldehyde-alcohol, and a urea condensate modified with formaldehyde or formaldehyde-alcohol, etc.

The modified melamine condensate includes a compound obtained by addition condensation polymerization of a compound represented by formula (D1) or a multimer thereof, for example, an oligomer such as a dimer or trimer, and formaldehyde until a desired molecular weight is reached. The addition condensation polymerization method may be a conventionally known method. One kind of the modified melamine represented by formula (D1) may be used alone or two or more kinds thereof may be used in combination.

Examples of urea condensates modified with formaldehyde or formaldehyde-alcohol include methoxymethylated urea condensates, ethoxymethylated urea condensates, propoxymethylated urea condensates, etc.

The modified urea condensate can be obtained, for example, by modifying a urea condensate having a desired molecular weight with formaldehyde through methylolation according to a known method, or by further modifying the urea condensate with alcohol through alkoxylation.

Examples of the phenol compound having two or more methylol groups or alkoxymethyl groups on average in one molecule include (2-hydroxy-5-methyl)-1,3-benzenedimethanol, 2,2′,6,6′-tetramethoxymethylbisphenol A, etc.

Examples of the epoxy compounds having two or more epoxy groups on average in one molecule include: bisphenol type epoxy resins such as bisphenol A type epoxy resins and bisphenol F type epoxy resins; novolac type epoxy resins such as phenol novolac type epoxy resins and cresol novolac type epoxy resins; triphenol alkane type epoxy resins; biphenyl type epoxy resins; dicyclopentadiene-modified phenol novolac type epoxy resins; phenol aralkyl type epoxy resins; biphenyl aralkyl type epoxy resins; naphthalene ring-containing epoxy resins; glycidyl ester type epoxy resins; alicyclic epoxy resins; heterocyclic type epoxy resins; etc.

When the component (D) is contained, the content is preferably 0.5 to 50 parts by mass, more preferably 1 to 30 parts by mass, relative to 100 parts by mass of the component (A). When the content is 0.5 parts by mass or more, sufficient curability is achieved at the light irradiation. When the content is 50 parts by mass or less, the proportion of the component (A) in the photosensitive resin composition does not decrease to enable the cured product to exhibit sufficient effects. One kind of the component (D) may be used alone, or two or more kinds thereof may be used in combination.

### [(E) Solvent]

The inventive photosensitive resin composition may contain a solvent as a component (E). The solvent (E) is not particularly limited, as long as it can dissolve in the above-described components (A) to (D) and other various additives described later. However, it is preferable that the organic solvent has an excellent solubility in these components.

Examples of the organic solvent include: ketones such as cyclohexanone, cyclopentanone, and methyl-2-n-pentyl ketone; alcohols such as 3-methoxybutanol, 3-methyl-3-methoxybutanol, 1-methoxy-2-propanol, and 1-ethoxy-2-propanol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol-mono-tert-butyl ether acetate, and γ-butyrolactone; etc. Particularly, the solvent is preferably ethyl lactate, cyclohexanone, cyclopentanone, PGMEA, γ-butyrolactone, and mixed solvents thereof, which have the best solubility in the photo-acid generator.

A mount of the component (E) to be used is preferably 50 to 2000 parts by mass, more preferably 50 to 1000 parts by mass, particularly preferably 50 to 100 parts by mass, relative to 100 parts by mass of the components (A), from the viewpoints of compatibility and viscosity of the photosensitive resin composition. One kind of the component (E) may be used alone or two or more kinds thereof may be used in combination.

### [Other Additives]

The inventive photosensitive resin composition may contain other additives, besides the above-described components. Examples of the other additives include, for example, a surfactant commonly used to enhance coatability.

The surfactant is preferably nonionic. Examples thereof include fluorine-based surfactants, specifically, perfluoroalkyl polyoxyethylene ethanols, fluorinated alkyl esters, perfluoroalkylamine oxides, fluorine-containing organosiloxane-based compounds, etc. These may be commercially available products. Examples thereof include Fluorad (registered trademark) “FC-430” (manufactured by 3M Company), Surflon (registered trademark) “S-141” and “S-145” (manufactured by AGC SEIMI CHEMICAL CO., LTD.), UNIDYNE (registered trademark) “DS-401”, “DS-4031”, and “DS-451” (manufactured by DAIKIN INDUSTRIES, LTD.), Megafac (registered trademark) “F-8151” (manufactured by DIC Corporation), “X-70-093” (manufactured by Shin-Etsu Chemical Co., Ltd.), etc. Among these, Fluorad FC-430 and X-70-093 are preferable. The content of the surfactant is preferably 0.05 to 1 parts by mass relative to 100 parts by mass of the component (A).

The inventive photosensitive resin composition may contain a silane coupling agent as other additives. Incorporating a silane coupling agent can further enhance the adhesiveness of a film obtained from the photosensitive resin composition to the adhered. Examples of the silane coupling agents include epoxy group-containing silane coupling agents, aromatic group-containing amino silane coupling agents, etc. One kind of these may be used alone or two or more kinds thereof may be used in combination. The content of the silane coupling agent is not particularly limited. When the silane coupling agent is contained, the content in the inventive photosensitive resin composition is preferably 0.01 to 5 mass %.

The inventive photosensitive resin composition can be prepared according to a conventional method. For example, the components are mixed by stirring, and then filtered using a filter or the like to remove solids, as necessary, to prepare the inventive photosensitive resin composition.

The inventive photosensitive resin composition prepared in this way is suitably used, for example, as a material of a protective film for semiconductor elements, a protective film for wiring, a coverlay film, a solder mask, and an insulating film for through electrodes (for TSV), and further as an adhesive between laminated substrates in three-dimensional lamination.

### [Pattern-Forming Process Using Photosensitive Resin Composition]

The inventive pattern-forming process using the inventive photosensitive resin composition includes steps of:
(i) forming a photosensitive resin film on a substrate using the inventive photosensitive resin composition;
(ii) exposing the photosensitive resin film; and
(iii) developing the exposed photosensitive resin film with a developer to form a pattern.

The step (i) is a step in which a photosensitive resin film is formed on a substrate using the photosensitive resin composition. The photosensitive resin film is a dried product of the above-described photosensitive resin composition. Examples of the substrate include, for example, a silicon wafer, a silicon wafer for a through electrode, a silicon wafer thinned by back polishing, a plastic or ceramic substrate, a substrate that has metals such as Ni, Au, etc. on the entire surface or a part of the substrate by ion sputtering method, plating method, etc. Further, a substrate having asperities may be used.

Methods to form the photosensitive resin film can include, for example, applying the photosensitive resin composition onto a substrate and then pre-heating (pre-baking) as necessary. The applying method may be a known method and examples thereof include a dip method, a spin coating method, a roll coating method, etc. The amount of the photosensitive resin composition applied can be appropriately selected depending on the purpose, but it is preferable to apply the composition so that the thickness of the resulting photosensitive resin film is preferably 0.1 to 200 μm, more preferably 1 to 150 μm.

To enhance the film thickness uniformity on a substrate surface, a solvent may be dropped on the substrate before the photosensitive resin composition is applied (pre-wetting method). The solvent to be dropped and its amount can be appropriately selected in accordance with the purpose. Preferable examples of the solvent include: alcohols such as isopropyl alcohol (IPA); ketones such as cyclohexanone; glycols such as PGME; etc. It is also possible to use the solvent used for the photosensitive resin composition.

In this event, pre-baking may be performed to evaporate the solvent or the like in advance as necessary for an efficient photo-curing reaction. The pre-baking can be performed, for example, at 40 to 140° C. for about 1 minute to 1 hour.

Then, (ii) the photosensitive resin film is exposed. In this event, the exposure is preferably performed with light having a wavelength of 10 to 600 nm, more preferably performed with light having a wavelength of 190 to 500 nm. The light having such wavelengths are, for example, light having various wavelengths generated from a radiation-beam generating instrument. Examples of the light include ultraviolet light such as a g-line, an h-line, and an i-line; far ultraviolet light (248 nm, 193 nm); etc. Among these, light having a wavelength of 248 to 436 nm is particularly preferable. The exposure dose is preferably 10 to 10000 mJ/cm².

The exposure may be performed via a photomask. The photomask may, for example, be hollowed out in a desired pattern. Note that, the material of the photomask is not particularly limited, but is preferably one that blocks light having the aforementioned wavelength. For example, a photomask having a light-blocking film made of chromium is suitably used.

Further, in order to enhance the development sensitivity, the post-exposure baking (PEB) may be carried out. The PEB is preferably performed at 40 to 150° C. for 0.5 to 10 minutes. PEB makes the exposed part crosslinked to form an insoluble pattern that is insoluble in an organic solvent, which is a developer.

(iii) The exposed photosensitive resin film is developed with a developer after the exposure or PEB to form a pattern. The developer is preferably an organic solvent, and examples thereof include: alcohols such as IPA; ketones such as cyclohexanone; glycols such as PGME; etc. It is also possible to use the solvent used for the photosensitive resin composition. Examples of the development method include usual methods, for example, a method in which the patterned substrate is soaked into the developer; etc. By the development with such organic solvent, the unexposed portion is dissolved and removed, so that a pattern is formed. Then, if necessary, washing, rinsing, drying, etc. are carried out to obtain a film having a desired pattern.

Further, (iv) the patterned film may be post-cured by using an oven or hot plate, at preferably 100° C. to 250° C., more preferably 130 to 220° C. A resin film excellent in various film properties can be obtained by using the inventive photosensitive resin composition even when the post-curing is performed at 100° C. to 250° C., it is possible to increase the crosslinking density of the photosensitive resin composition and remove residual volatile components, and thus it is preferable from the viewpoints of adhesiveness to the substrate, heat resistance, strength, electrical properties, and adhesive strength. The post-curing time is preferably 10 minutes to 10 hours, more preferably 10 minutes to 3 hours. By using the inventive photosensitive resin composition, a film having excellent various film properties can be obtained even when post-curing is performed at a relatively low temperature of 200° C. or lower. After the post-curing, the resin film, or the cured film, has a thickness of normally 1 to 200 μm, preferably 5 to 50 μm.

When it is unnecessary to form a pattern, for example, when it is simply desired to form a uniform film, in the step (ii) of the pattern-forming process the resin film may be exposed to radiation of suitable wavelength without the photomask to form a film. [Substrate Bonding Method]

The inventive photosensitive resin composition may also be used as an adhesive for bonding two substrates. The substrate bonding method includes a method of joining a first substrate having a film of the inventive photosensitive resin composition formed thereon to a second substrate under a suitable temperature and pressure conditions so that an adhesive bond between the two substrates can be formed. One or both of the substrate having a resin film formed and the second substrate may have been cut into a chip such as by dicing. As the preferred bonding conditions, the temperature is preferably 50 to 200° C., and the time is preferably 1 to 60 minutes. As for bonding apparatus, a wafer bonder may be used for bonding wafers each other under reduced pressure and under a certain load, or a flip chip bonder may be used for performing chip-wafer or chip-chip bonding. The adhesive layer between substrates obtains enhanced bond strength by post-cure treatment described later, and the bond becomes permanent.

By the post-curing the joined or bonded substrates under the same conditions as in the above step (iv), the crosslinking density of the film increases and the substrate bonding force can be enhanced. Note that, although crosslinking reaction occurs by the heat during bonding, no joining failure, or a void, is induced particularly when the composition is used as the substrate adhesive because the crosslinking reaction is not accompanied by side reaction entailing degassing.

### [Photosensitive Dry Film]

The inventive photosensitive dry film includes: a support film; and a photosensitive resin film obtained from the photosensitive resin composition on the support film.

The photosensitive dry film, which includes a support film and a photosensitive resin film, is solid, and the photosensitive resin film does not contain a solvent. Accordingly, there is no risk that bubbles due to the volatilization of the solvent remain in the photosensitive resin film and between the film and a substrate having asperities.

The thickness of the photosensitive resin film is preferably 5 to 200 μm, more preferably 10 to 100 μm, from the viewpoint of flatness of the substrate having asperities on its surface, step-covering property, and a lamination interval.

In addition, the viscosity and fluidity of the photosensitive resin film are closely related. The photosensitive resin film can exhibit appropriate fluidity in an appropriate viscosity range; can deeply enters into a narrow gap; and can enhance adhesiveness to a substrate by softening of the resin. Thus, the photosensitive resin film has a viscosity of preferably 10 to 5000 Pas, more preferably 30 to 2000 Pa·s, further preferably 50 to 300 Pas, at 80 to 120° C. from the viewpoint of the fluidity of the photosensitive resin film. Note that, in the present invention, the viscosity is a value measured with a rotational viscometer.

When the inventive photosensitive dry film is brought into close contact with a substrate having asperities on its surface, the photosensitive resin film fits in and covers the asperities, so that high flatness can be achieved. Particularly, the inventive photosensitive resin composition is characterized by softening performance, so that higher planarization can be achieved. Further, when the photosensitive resin film was brought into close contact with the substrate under vacuum environment, it is possible to prevent a gap between them more effectively.

The inventive photosensitive dry film can be produced by applying the photosensitive resin composition onto a support film and drying the composition to form a photosensitive resin film. As production apparatus for the photosensitive dry film, it is possible to employ a film coater which is commonly used to produce adhesive products. Examples of the film coater include a comma coater, a comma reverse coater, a multi coater, a die coater, a lip coater, a lip reverse coater, a direct gravure coater, an offset gravure coater, a 3-roll bottom reverse coater, a 4-roll bottom reverse coater, etc.

The photosensitive dry film can be produced by applying the photosensitive resin composition onto the support film to have a predetermined thickness when the support film is rolled-out from a roll-out shaft of the film coater and passes through a coater head of the film coater, then having the resultant passed through a hot-air circulating oven at a predetermined temperature for a predetermined period to dry to form the photosensitive resin film on the support film. The photosensitive dry film with a protective film can be produced by: passing the photosensitive dry film through a laminate roll under a predetermined pressure together with the protective film that was rolled-out from another roll-out shaft of the film coater to join the protective film to the photosensitive resin film on the support film; and subsequently winding up the resulting laminate to a winding shaft of the film coater. In this event, the temperature is preferably 25 to 150° C., the period is preferably 1 to 100 minutes, and the pressure is preferably of 0.01 to 5 MPa.

The support film may be a monolayer film composed of a single film or a multilayer film composed of multiple laminated films. Examples of the material of the film include synthetic resin films such as polyethylene, polypropylene, polycarbonate, and polyethylene terephthalate. Among these, polyethylene terephthalate is a preferable material because of having appropriate flexibility, mechanical strength, and heat resistance. These films may have been subjected to various treatments, such as corona treatment and coating treatment with a releasing agent. Commercial products may be used for these. Examples thereof include: Cerapeel WZ (RX) and Cerapeel BX8 (R), both are manufactured by Toray Advanced Film Co., Ltd.; E7302 and E7304, both are manufactured by Toyobo Co., Ltd.; Purex G31 and Purex G71T1, both are manufactured by Teijin DuPont Films Japan Ltd.; PET38x1-A3, PET38x1-V8, and PET38x1-X08, all manufactured by Nippa Co., Ltd.; etc.

The protective film to be used may be the same film as the above-mentioned support film, but polyethylene terephthalate and polyethylene are preferable because they have appropriate flexibility. Commercial products may be used for these. Examples thereof include: the polyethylene terephthalates exemplified above; polyethylenes such as GF-8 manufactured by Tamapoly Co., Ltd.; PE Film 0-Type manufactured by Nippa Co. Ltd.; etc.

The thicknesses of both the support film and the protective film are preferably 10 to 100 μm, more preferably 25 to 50 μm, from the viewpoints of stable production of the photosensitive dry film and the prevention of rolling habit around a roll shaft, or so-called “curl-prevention”.

### [Pattern-Forming Process Using Photosensitive Dry Film]

The pattern-forming process using the inventive photosensitive dry film includes steps of:
(i′) forming a photosensitive resin film on a substrate by using the inventive photosensitive dry film;
(ii) exposing the photosensitive resin film; and
(iii) developing the exposed photosensitive resin film with a developer to form a pattern.

First, in the step (i′), the photosensitive dry film is used to form the photosensitive resin film on a substrate. Specifically, the photosensitive resin film of the photosensitive dry film is bonded to a substrate, to form the photosensitive resin film on the substrate. In the case where the photosensitive dry film has a protective film, after removing the protective film from the photosensitive dry film, the photosensitive resin film of the photosensitive dry film is bonded to the substrate. The bonding can be performed, for example, by using a film sticking apparatus.

Examples of the substrate include the same substrates as exemplified above in the pattern-forming process using photosensitive dry film. The film sticking apparatus is preferably a vacuum laminator. For example, the protective film of the photosensitive dry film is delaminated, and the uncovered photosensitive resin film is brought into close contact with the substrate on a table at a predetermined temperature by using a sticking roll under a predetermined pressure in a vacuum chamber with a predetermined degree of vacuum. Note that, the temperature is preferably 60 to 120° C., the pressure is preferably 0 to 5.0 MPa, and the degree of vacuum is preferably 50 to 500 Pa.

The attachment of dry film may be repeated plural times if necessary to obtain a photosensitive resin film having the desired thickness. With repeating the attachment step 1 to 10 times, for example, a photosensitive resin film having a thickness of 10 to 1000 μm, particularly about 100 to 500 μm can be obtained.

In order to perform an efficient photo-curing reaction of the photosensitive resin film and to improve adhesiveness between the photosensitive resin film and the substrate, pre-baking may be performed as necessary. The pre-baking can be performed, for example, at 40 to 140° C. for about 1 minute to 1 hour.

In the same manner as the pattern-forming process using photosensitive resin composition, the photosensitive resin film adhered on the substrate can have a pattern formed by (ii) exposing the photosensitive resin film, (iii) developing the exposed photosensitive resin film with a developer to form a pattern, and as necessary (iv) post-curing the photosensitive resin film. Note that, the support film of the photosensitive dry film is delaminated before the pre-bake or before the PEB depending on the process or removed by other methods.

The inventive photosensitive resin composition can be a material of a film for protecting an electric and electronic part or a material of a substrate-bonding film for bonding two substrates.

A film obtained from the photosensitive resin composition has excellent mechanical properties such as solder resistance, heat resistance, low substrate warpage, and crack resistance; copper migration resistance; and adhesiveness to substrates, and is suitably used as a film for protecting an electric and electronic part such as a semiconductor element or a substrate-bonding film. These films can also be formed using the inventive photosensitive dry film.

As described above, the present invention can provide: a photosensitive resin composition that can easily form a thick and fine pattern without causing discoloration of copper and can form a resin film (resin layer) that is excellent in various film properties such as copper migration resistance, adhesiveness to a substrate, an electronic part, a semiconductor device, etc., especially to a base material used for a circuit board, and reliability as a film for protecting an electric and electronic part, a substrate-bonding film, etc.; a photosensitive resin film formed using the photosensitive resin composition; a photosensitive dry film; and a pattern-forming process using these.

### EXAMPLE

Hereinafter, the present invention will be more specifically described with reference to Synthesis Examples, Examples, and Comparative Examples. However, the present invention is not limited to the following Examples. Note that, the weight-average molecular weight (Mw) is measured by GPC using TSKgel Super HZM-H manufactured by Tosoh Corporation as the column using monodisperse polystyrene as the standard under the following analytical conditions: flow rate of 0.6 mL/min, THF for elution solvent, and column temperature of 40° C.

Compounds (S-1) to (S-5) used in the Synthesis Examples are shown below.

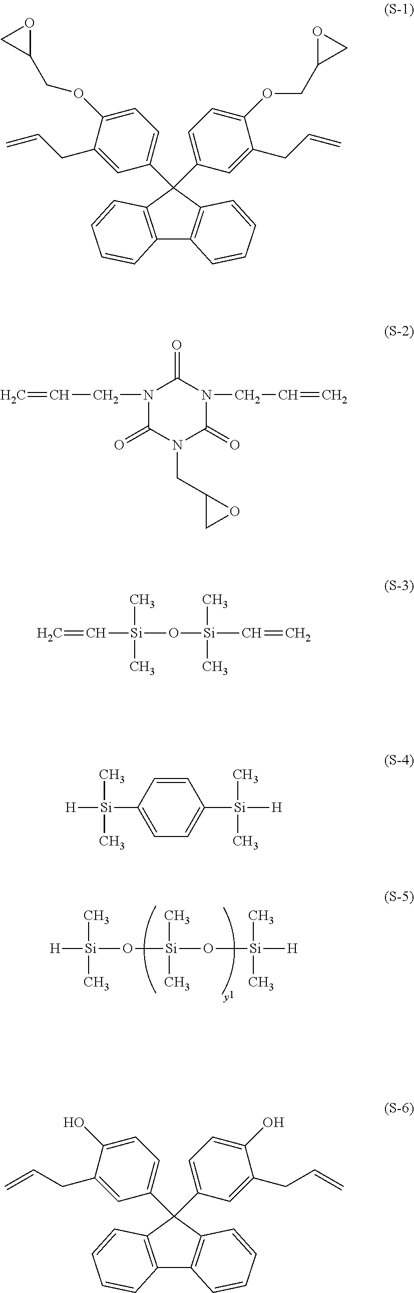

### [1] Synthesis of Silicone Resin

### Synthesis Example 1

Into a 3-L flask equipped with a stirrer, a thermometer, a nitrogen substitution instrument, and a reflux condenser, 215.0 g (0.5 mol) of Compound (S-6) was introduced, 2000 g of toluene was added thereto, and the mixture was heated to 70° C. Subsequently, 1.0 g of toluene solution of chloroplatinic acid (platinum concentration: 0.5 mass %) was introduced, and 67.9 g (0.35 mol) of Compound (S-4) and 453.0 g (0.15 mol) of Compound (S-5) (y¹=40, manufactured by Shin-Etsu Chemical Co., Ltd.) were added dropwise over 1 hour (total of hydrosilyl groups/total of alkenyl groups=1/1, in a ratio by mole). After completion of the dropwise addition, the mixture was heated to 100° C. and aged for 6 hours. Thereafter, toluene was evaporated from the reaction solution under reduced pressure, and Silicone Resin A-1 was obtained. The structure of Resin A-1 was confirmed to contain repeating units a2 and b2 by 1H-NMR manufactured by Bruker Corporation. Silicone Resin A-1 had a Mw of 62000 and a silicone content percentage of 61.6 mass %.

### Synthesis Example 2

Into a 3-L flask equipped with a stirrer, a thermometer, a nitrogen substitution instrument, and a reflux condenser, 53.00 g (0.20 mol) of Compound (S-2) and 117.6 g (0.30 mol) of Compound (S-1) was introduced, 2000 g of toluene was added thereto, and the mixture was heated to 70° C. Subsequently, 1.0 g of toluene solution of chloroplatinic acid (platinum concentration: 0.5 mass %) was introduced, and 48.5 g (0.25 mol) of Compound (S-4) and 755.0 g (0.25 mol) of Compound (S-5) (y¹=40, manufactured by Shin-Etsu Chemical Co., Ltd.) were added dropwise over 1 hour (total of hydrosilyl groups/total of alkenyl groups=1/1, in a ratio by mole). After completion of the dropwise addition, the mixture was heated to 100° C. and aged for 6 hours. Thereafter, toluene was evaporated from the reaction solution under reduced pressure, and Silicone Resin A-2 was obtained. The structure of Resin A-2 was confirmed to contain repeating units a1, a3, b1, and b3 by ¹H-NMR manufactured by Bruker Corporation. Silicone Resin A-2 had a Mw of 83000 and a silicone content percentage of 77.5 mass %.

### Synthesis Example 3

Into a 3-L flask equipped with a stirrer, a thermometer, a nitrogen substitution instrument, and a reflux condenser, 27.9 g (0.15 mol) of Compound (S-3), 19.6 g (0.05 mol) of Compound (S-1), and 129.0 g (0.30 mol) of Compound (S-6) was introduced, 2000 g of toluene was added thereto, and the mixture was heated to 70° C. Subsequently, 1.0 g of toluene solution of chloroplatinic acid (platinum concentration: 0.5 mass %) was introduced, and 87.3 g (0.45 mol) of Compound (S-4) and 79.3 g (0.05 mol) of Compound (S-5) (y¹=20, manufactured by Shin-Etsu Chemical Co., Ltd.) were added dropwise over 1 hour (total of hydrosilyl groups/total of alkenyl groups=1/1, in a ratio by mole). After completion of the dropwise addition, the mixture was heated to 100° C. and aged for 6 hours. Thereafter, toluene was evaporated from the reaction solution under reduced pressure, and Silicone Resin A-3 was obtained. The structure of Resin A-3 was confirmed to contain repeating units a1, a2, a4, b1, b2, and b4 by 1H-NMR manufactured by Bruker Corporation. Silicone Resin A-3 had a Mw of 24000 and a silicone content percentage of 31.2 mass %.

### [2] Preparation of Photosensitive Resin Compositions

### Examples 1 to 8 and Comparative Examples 1 to 16

In accordance with the formulation amounts shown in Tables 1 to 3, the components each were blended, stirred at normal temperature, and dissolved. Then, the mixture was subjected to precision filtering through a Teflon® filter with a pore size of 1.0 μm, and photosensitive resin compositions of Examples 1 to 8 and Comparative Examples 1 to 16 were prepared.

TABLE 1

| | | | Example | | | | | | | |
|---|---|---|---|---|---|---|---|---|---|---|
| Component | | | 1 | 2 | 3 | 4 | 5 | 6 | 7 | 8 |
| A | Silicone | A-1 | | | 100 | | | 100 | | |
| | Resin | A-2 | 100 | | | 100 | | | 100 | |
| | | A-3 | | 100 | | | 100 | | | 100 |
| B | Oxazoline | B-1 | 0.1 | | | | | | 0.5 | |
| | compound | B-2 | | 0.3 | | | | | 0.5 | 0.5 |
| | | B-3 | | | 0.5 | | | | | 0.5 |
| | | B-4 | | | | 1 | | | | |
| | | B-5 | | | | | 3 | | | |
| | | B-6 | | | | | | 1 | | |
| C | Photo-acid | PAG-1 | 1 | | | 5 | | | 2.5 | |
| | generator | PAG-2 | | 3 | | | 10 | | 2.5 | 2.5 |
| | | PAG-3 | | | 5 | | | 5 | | 2.5 |
| D | Cross- | CL-1 | | | 10 | | 20 | 15 | | 5 |
| | linker | CL-2 | | | | 20 | 30 | | | |
| E | Solvent | Cyclo- | 55 | 55 | 55 | 55 | 55 | 55 | 55 | 55 |
| | | penta- | | | | | | | | |
| | | none | | | | | | | | |

TABLE 2

| | | | Comparative Example | | | | | | | | | |
|---|---|---|---|---|---|---|---|---|---|---|---|---|
| Component | | | 1 | 2 | 3 | 4 | 5 | 6 | 7 | 8 | 9 | 10 |
| A | Resin | A-1 | | | 100 | | | | | | | |
| | | A-2 | 100 | | | 100 | | | | | | |
| | | A-3 | | 100 | | | | | | | | |
| | | A-1′ | | | | | 100 | 100 | 100 | 100 | 100 | 100 |
| B | Additive | B-1 | | | | | 0.1 | | | | | |
| | | B-2 | | | | | | 0.3 | | | | |
| | | B-3 | | | | | | | 0.5 | | | |
| | | B-4 | | | | | | | | 1 | | |
| | | B-5 | | | | | | | | | 3 | |
| | | B-6 | | | | | | | | | | 1 |
| C | Photo- | PAG-1 | 1 | | | 2.5 | 1 | | | 5 | | |
| | acid | PAG-2 | | 3 | | 2.5 | | 3 | | | 10 | |
| | generator | PAG-3 | | | 5 | | | | 5 | | | 5 |
| D | Cross- | CL-1 | | | 10 | | 5 | 10 | 20 | 5 | 5 | 5 |
| | linker | CL-2 | | | | 20 | | | | 10 | 20 | 30 |
| E | Solvent | Cyclo- | 55 | 55 | 55 | 55 | 55 | 55 | 55 | 55 | 55 | 55 |
| | | penta- | | | | | | | | | | |
| | | none | | | | | | | | | | |

TABLE 3

| | | | Comparative Example | | | | | |
|---|---|---|---|---|---|---|---|---|
| Component | | | 11 | 12 | 13 | 14 | 15 | 16 |
| A | Resin | A-1 | | | 100 | | | 100 |
| | | A-2 | 100 | | | 100 | | |
| | | A-3 | | 100 | | | 100 | |
| B | Additive | B′-1 | 0.1 | | | | | |
| | | B′-2 | | 0.3 | | | | |
| | | B′-3 | | | 0.5 | | | |
| | | B′-4 | | | | 1 | | |
| | | B′-5 | | | | | 3 | |
| | | B′-6 | | | | | | 1 |
| C | Photo-acid | PAG-1 | 1 | | | 5 | | |
| | generator | PAG-2 | | 3 | | | 10 | |
| | | PAG-3 | | | 5 | | | 5 |
| D | Crosslinker | CL-1 | | | 10 | | 20 | 15 |
| | | CL-2 | | | | 20 | 30 | |
| E | Solvent | Cyclopentanone | 55 | 55 | 55 | 55 | 55 | 55 |

In Tables 1 to 3, B-1 to B-6 and B′-1 to B′-6 are as follows. Note that, the compounds B-1 to B-6 correspond to the inventive component (B), but the compounds B′-1 to B′-6 do not.

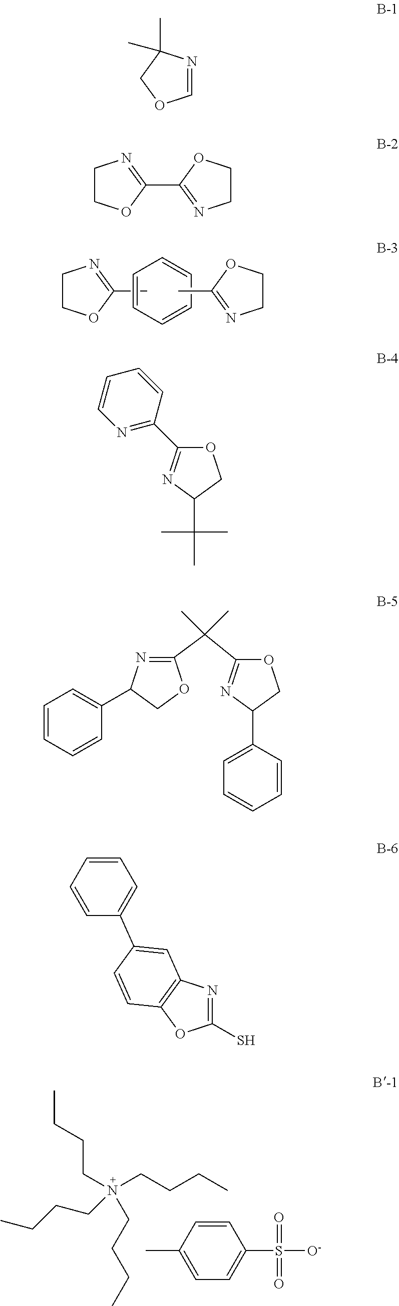

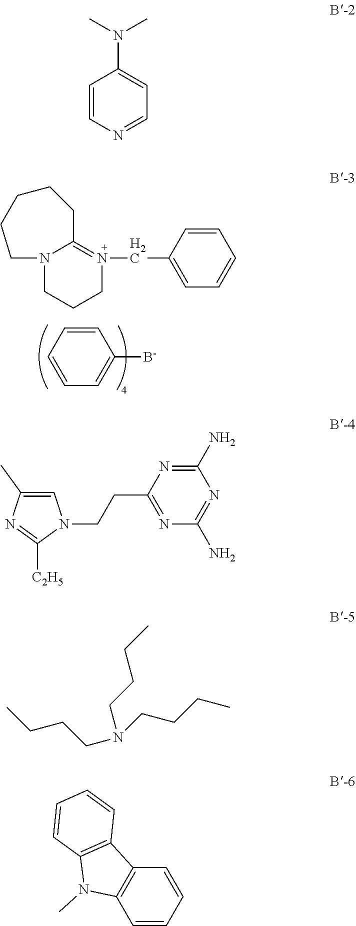

In Tables 1 to 3, photo-acid generators PAG-1 to PAG-3 are as follows.

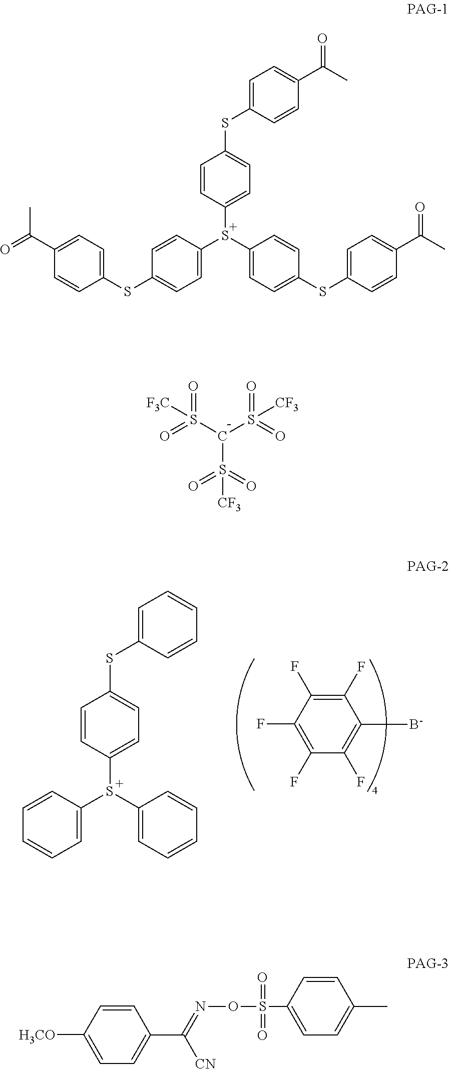

In Tables 1 to 3, crosslinkers CL-1 and CL-2 are as follows.

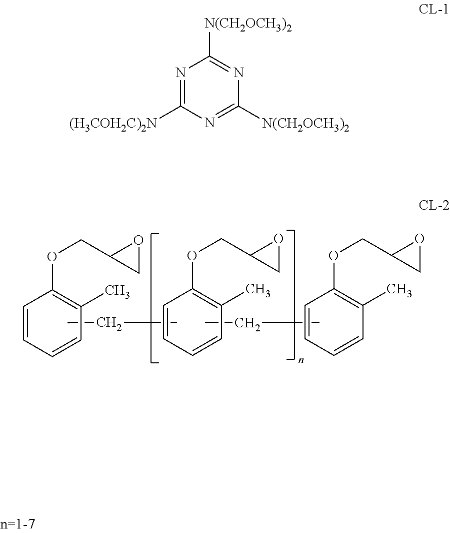

In Table 2, Resin A′-1 is as follows. Note that, Resin A′-1 does not fall under the component (A) of the present invention.

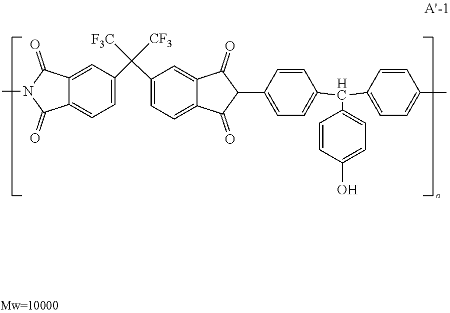

### [3] Preparation of Photosensitive Dry Film

Using a die coater as a film coater and a polyethylene terephthalate film (thickness: 38 μm) as a support film the photosensitive resin compositions shown in Tables 1 to 3 were respectively applied onto the support film. Then, the applied support film was dried by passing through a hot-air circulating oven (length: 4 m) set at 100° C. for 5 minutes. Thereby, a photosensitive resin film was formed on the support film, and a photosensitive dry film was obtained. A polyethylene film (thickness: 50 μm) as a protective film was laminated onto the photosensitive resin film at a pressure of 1 MPa using a laminate roll, and a photosensitive dry film with a protective film was prepared. Each photosensitive dry film had a thickness of 80 μm. The thickness of a photosensitive resin film was measured by an optical interference film thickness measurement instrument (F50-EXR by Filmetrics Co.).

### [4] Evaluation of Resin Film

### (1) Pattern Forming and Evaluation Thereof

The protective film was stripped off from the photosensitive dry film with a protective film. Using a vacuum laminator TEAM-100RF (Takatori Corp.) with a vacuum chamber set at a vacuum of 80 Pa, the photosensitive resin film on the support film was closely bonded to a migration test substrate (a substrate with comb-shaped electrode, conductor: copper, conductor spacing and width: 10 μm, conductor thickness: 4 μm). The temperature was 100° C. After returning to normal pressure, the substrate was taken out of the vacuum laminator, and the support film was stripped off. Then the photosensitive resin film was prebaked on a hot plate at 120° C. for 5 minutes for enhancing its adhesiveness to the substrate. Next, using a contact aligner exposure tool, the obtained photosensitive resin film was exposed to radiation of wavelength 365 nm through a mask for forming a line-and-space pattern and a contact hole pattern in the photosensitive resin film. After exposure, the photosensitive resin film was baked (PEB) on a hot plate at 140° C. for 5 minutes and cooled. This was followed by spray development in PGMEA for 300 seconds to form a pattern of the resin film.

The photosensitive resin film on the substrate patterned by the above method was post-cured in an oven at 170° C. for 1 hour while purging with nitrogen. Then, under a scanning electron microscope (SEM), the formed contact hole patterns of 100 μm, 80 μm, 50 μm, and 40 μm were observed in cross-section. The minimum hole pattern in which a hole extended down to the film bottom was defined as a resolution limit. From the observed cross-sectional photo, the contact hole pattern of 80 μm was evaluated for perpendicularity, and rated “Excellent” for perpendicular pattern, “Good” for slight inversely tapered profile or footing, “Fair” for outstanding inversely tapered profile or footing, and “Poor” for opening failure. The results are shown in Tables 4 to 6.

### (2) Evaluation of Electric Properties (Copper Migration)

A test was performed using the substrate having the pattern formed by the method of (1) as the substrate for evaluating copper migration. The copper migration test was performed under conditions: temperature 130° C., humidity 100%, and applied voltage 20 V. The time passed until short-circuiting occurred was measured, with the upper limit set at 1000 hours. The results are shown in Tables 4 to 6.

### (3) Discoloring Property on Copper Surface

The protective film was stripped off from the photosensitive dry film with a protective film. Using a vacuum laminator TEAM-100RF (Takatori Corp.) with a vacuum chamber set at a vacuum of 80 Pa, the photosensitive resin film on the support film was closely bonded to a substrate on which a copper film was formed by spattering at a thickness of 350 nm. The temperature was 100° C. After returning to normal pressure, the substrate was taken out of the vacuum laminator, and the support film was stripped off. Then the photosensitive resin film was prebaked on a hot plate at 120° C. for 5 minutes for enhancing its adhesiveness to the substrate. Next, using a contact aligner exposure tool, the obtained photosensitive resin film was exposed to radiation of wavelength 365 nm through a mask for forming a line-and-space pattern and a contact hole pattern in the photosensitive resin film. After exposure, the photosensitive resin film was baked (PEB) on a hot plate at 140° C. for 5 minutes and cooled. This was followed by spray development in PGMEA for 300 seconds to form a contact hole pattern of 1 cm×1 cm. The photosensitive resin film on the substrate was post-cured in an oven at 170° C. for 1 hour. Then, copper surface in the contact hole was observed visually and and rated “Good” for no discoloration and “Poor” for discoloration. The results are shown in Tables 4 to 6.

### (4) Evaluation of Reliability (Adhesiveness, Crack Resistance)

From the photosensitive dry film with a protective film, the protective film was stripped off. Using a vacuum laminator TEAM-100RF (Takatori Corp.) with a vacuum chamber set at a vacuum of 80 Pa, the photosensitive resin film on the support film was closely bonded to a CCL substrate having silicon chips of 10 mm squares laid thereon. The temperature was 100° C. After returning to normal pressure, the substrate was taken out of the vacuum laminator, and the support film was stripped off. Then the photosensitive resin film was prebaked on a hot plate at 120° C. for 5 minutes for enhancing its adhesiveness to the substrate. Next, using a contact aligner exposure tool, the obtained photosensitive resin film was exposed to radiation of wavelength 365 nm without a mask. After exposure, the photosensitive resin film was baked (PEB) on a hot plate at 140° C. for 5 minutes, cooled, and post-cured in an oven at 170° C. for 1 hours while purging with nitrogen. Thereafter, using a dicing saw (DAD685 by DISCO Co., spindle revolution 40000 rpm, cutting rate 20 mm/sec) with a dicing blade, the substrate was cut into specimens of 20 mm squares so that the outer periphery of the silicon chip was 5 mm. The obtained specimens (ten specimens for each Example) were examined by a thermal cycling test where a cycle of holding at −55° C. for 10 min followed by holding at 125° C. for 10 min was repeated 1000 times. After the thermal cycling test, it was observed whether or not the resin film peeled from the wafer and whether or not the resin film cracked. An Example was rated “Good” when all specimens of the Example did not peel or crack, and an Example was rated “Poor” when one or more specimens peeled off or cracked. The means for determining whether or not a specimen peeled or cracked were top-down observation under an optical microscope and cross-sectional observation by the SEM. The results are shown in Tables 4 to 6.

### (5) Evaluation of Adhesive Strength (Initial: Before Heat Resistance Test)

From the photosensitive dry film with a protective film, the protective film was stripped off. Using a vacuum laminator TEAM-100RF (Takatori Corp.) with a vacuum chamber set at a vacuum of 80 Pa, the photosensitive resin film on the support film was closely bonded to an 8-inch silicon wafer, and then was prebaked on a hot plate at 120° C. for 5 minutes to obtain a substrate with a resin film (wafer). A separately prepared 8-inch silicon wafer was cut into 20 mm squares using a dicing saw (DAD685 by DISCO Co.) with a dicing blade. The five 2 mm square chips were bonded onto the substrate with a resin film via the resin film under a load of 50 mN at 130° C. Then, the substrate was heated at 170° C. for 1 hour to cure the resin film, and used for a test to measure adhesive strength. The resistance force applied when a 2 mm square semiconductor chip is peeled from a base substrate (15 mm square silicon wafer) was measured by using a bond tester (Dage series 4000-PXY, manufactured by Dage), and the adhesive strength of the resin film was evaluated. The test was carried out at the condition with a test speed of 200 μm/see and a test height of 50 μm. The results are shown in Tables 4-6. Note that, the numerical values are the average of the measured values of five test pieces, and the higher the numerical value, the higher the adhesive strength.

(6) Evaluation of Adhesive Strength (after Heat Resistance Test)

After leaving the test piece prepared for the adhesive strength measurement of the above (5) in an oven heated at 150° C. for 2000 hours, the test piece was taken out of the oven and subjected to the adhesive strength measurement test in the same manner as in (5). The results are shown in Tables 4-6.

### (7) Evaluation of Solvent Resistance

For evaluating solvent resistance, i.e., resistance to N-methyl-2-pyrrolidone (NMP) which is frequently used in forming semiconductor devices, substrates prepared in the same manner as used for wafer for (5) Evaluation of Adhesive Strength were immersed in NMP at 50° C. for 1 hour, the resin film was examined for film thickness change and outer appearance to evaluate solvent resistance. The sample was rated “Good” for no changes in film thickness and outer appearance and “Poor” when swell, etc. were found. The results are shown in Tables 4 to 6.

TABLE 4

| | | Example | | | | | | | |
|---|---|---|---|---|---|---|---|---|---|
| | | 1 | 2 | 3 | 4 | 5 | 6 | 7 | 8 |
| Pattern | Reso- | 60 | 60 | 40 | 40 | 40 | 40 | 60 | 40 |
| forming | lution | | | | | | | | |
| | limit | | | | | | | | |
| | (μm) | | | | | | | | |
| | Pattern | Good | Good | Ex- | Ex- | Ex- | Ex- | Good | Ex- |
| | shape | | | cel- | cel- | cel- | cel- | | cel- |
| | | | | lent | lent | lent | lent | | lent |
| Copper | | No | No | No | No | No | No | No | No |
| migration | | short- | short- | short- | short- | short- | short- | short- | short- |
| test | | cir- | cir- | cir- | cir- | cir- | cir- | cir- | cir- |
| 1000 hr | | cuit | cuit | cuit | cuit | cuit | cuit | cuit | cuit |
| (Time to short- | | | | | | | | | |
| circuit hr) | | | | | | | | | |
| Discoloration | | Good | Good | Good | Good | Good | Good | Good | Good |
| on copper | | | | | | | | | |
| surface | | | | | | | | | |
| Reli- | Adhe- | Good | Good | Good | Good | Good | Good | Good | Good |
| ability | sive- | | | | | | | | |
| | ness | | | | | | | | |
| | Crack | Good | Good | Good | Good | Good | Good | Good | Good |
| | resist- | | | | | | | | |
| | ance | | | | | | | | |
| Adhe- | Initial | 15 | 15 | 16 | 16 | 17 | 16 | 15 | 16 |
| sive | After | 15 | 15 | 16 | 16 | 17 | 16 | 15 | 16 |
| strength | heat | | | | | | | | |
| (MPa) | resist- | | | | | | | | |
| | ance | | | | | | | | |
| | test | | | | | | | | |

| | | | | | | | | |
|---|---|---|---|---|---|---|---|---|
| Solvent | Good | Good | Good | Good | Good | Good | Good | Good |
| resistance | | | | | | | | |

TABLE 5

| | | Comparative Example | | | | | | | | | |
|---|---|---|---|---|---|---|---|---|---|---|---|
| | | 1 | 2 | 3 | 4 | 5 | 6 | 7 | 8 | 9 | 10 |
| Pattern | Resolution | 100 | 100 | 100 | 100 | 100 | 100 | 100 | 100 | 100 | 100 |
| forming | limit | | | | | | | | | | |
| | (μm) | | | | | | | | | | |
| | Pattern | Fair | Fair | Fair | Fair | Fair | Fair | Fair | Fair | Fair | Fair |
| | shape | | | | | | | | | | |
| Copper migration test | | 600 | 600 | 600 | 600 | 400 | 500 | 400 | 400 | 500 | 500 |
| 1000 hr (Time to | | | | | | | | | | | |
| short-circuit hr) | | | | | | | | | | | |
| Discoloration on | | Poor | Poor | Poor | Poor | Poor | Poor | Poor | Poor | Poor | Poor |
| copper surface | | | | | | | | | | | |
| Reli- | Adhesiveness | Poor | Poor | Poor | Poor | Poor | Poor | Poor | Poor | Poor | Poor |
| ability | Crack | Poor | Poor | Poor | Poor | Poor | Poor | Poor | Poor | Poor | Poor |
| | resistance | | | | | | | | | | |
| Adhesive | Initial | 11 | 11 | 12 | 12 | 11 | 12 | 10 | 11 | 12 | 11 |
| strength | After heat | 10 | 10 | 11 | 11 | 9 | 11 | 9 | 10 | 10 | 9 |
| (MPa) | resistance | | | | | | | | | | |
| | test | | | | | | | | | | |

| | | | | | | | | | | |
|---|---|---|---|---|---|---|---|---|---|---|
| Solvent resistance | Poor | Poor | Poor | Poor | Poor | Poor | Poor | Poor | Poor | Poor |

TABLE 6

| | | Comparative Example | | | | | |
|---|---|---|---|---|---|---|---|
| | | 11 | 12 | 13 | 14 | 15 | 16 |
| Pattern | Resolution | 100 | 100 | 100 | 100 | 100 | 100 |
| forming | limit | | | | | | |
| | (μm) | | | | | | |
| | Pattern | Fair | Fair | Fair | Fair | Fair | Fair |
| | shape | | | | | | |
| Copper migration test | | 200 | 300 | 300 | 200 | 200 | 300 |
| 1000 hr (Time to | | | | | | | |
| short-circuit hr) | | | | | | | |
| Discoloration on copper | | Poor | Poor | Poor | Poor | Poor | Poor |
| surface | | | | | | | |
| Reliability | Adhesiveness | Poor | Poor | Poor | Poor | Poor | Poor |
| | Crack resistance | Poor | Poor | Poor | Poor | Poor | Poor |
| Adhesive | Initial | 12 | 12 | 13 | 13 | 14 | 13 |
| strength | After heat | 9 | 9 | 10 | 10 | 10 | 10 |
| (MPa) | resistance test | | | | | | |

| | | | | | | |
|---|---|---|---|---|---|---|
| Solvent resistance | Poor | Poor | Poor | Poor | Poor | Poor |

As shown in Table 4, the inventive photosensitive resin compositions (Examples 1 to 8) were capable of forming patterns with excellent resolution and shape, had good electrical properties (resistance to copper migration), were free of discoloration of the copper surface, and were excellent in reliability (adhesiveness, crack resistance), adhesive strength (heat resistance) and solvent resistance.

In contrast, as shown in Tables 5 and 6, the compositions of Comparative Examples 1 to 4 and 11 to 16 which do not contain the inventive component (B) and Comparative Examples 5 to 10 which do not contain the inventive component (A) were inferior in resolution limit and shape in pattern forming, were unable to suppress copper migration and discoloration, and were inferior in reliability, adhesive strength and solvent resistance.

B′-1 to B′-6, which are used in place of the inventive component (B) in Comparative Examples 11 to 16, are conventionally used as a curing agent or a curing aid for epoxy resins, but do not provide satisfactory results as described above. In particular, it is known that diaminotriazine compounds having an imidazole ring, which is used as a curing agent or a curing aid for epoxy resins, can suppress the discoloration of copper (see JPH07-33766 A), but such a compound, B′-4 (2,4-diamino-6-(2′-ethyl-4′-methylimidazolyl)ethyl-1,3,5-triazine), cannot suppress discoloration of copper and the characteristics of the formed pattern are also inferior, as shown by the results of Comparative Example 14, in which this compound is blended.

Thus, by combining (A) an acid-crosslinkable group-containing silicone resin with (B) an oxazoline compound or a derivative thereof, the present invention is able to exhibit excellent effects that could not be predicted from the prior art.

From the above results, the inventive photosensitive resin composition and the inventive photosensitive dry film are indicated to be easily able to form a thick, fine, and perpendicular pattern without causing discoloration of copper and have sufficient properties as a photosensitive materials. Additionally, the photosensitive resin film obtained from these has high chemical resistance to photoresist stripping solutions, etc., and is excellent in adhesiveness, electrical insulation, and resistance to copper migration. Furthermore, the resin film has high reliability as an insulating protective film, and could be suitably used as a material for forming a film for protecting an electric and electronic part such as circuit boards, semiconductor elements, and display elements. According to the present invention, it is possible to provide a photosensitive resin composition and a photosensitive dry film with higher reliability.

The present description includes the following embodiments.

[1]: A photosensitive resin composition comprising:
(A) an acid-crosslinkable group-containing silicone resin;
(B) an oxazoline compound or a derivative thereof; and
(C) a photo-acid generator.

[2]: The photosensitive resin composition according to the above [1], wherein
(A) the silicone resin is represented by the following formula (A1),

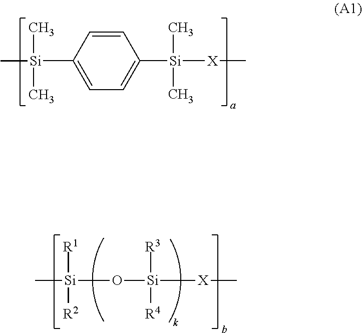

wherein R¹ to R⁴ each independently represent a hydrocarbyl group having 1 to 8 carbon atoms; “k” represents an integer of 1 to 600; “a” and “b” represent a composition ratio by mole of respective repeating units and represent numbers satisfying 0<a<1, 0<b<1, and a+b=1; and X represents a divalent organic group containing an epoxy group and/or a phenolic hydroxy group.

[3]: The photosensitive resin composition according to the above [1] or [2], wherein
(A) the silicone resin comprises repeating units represented by the following formulae (a1) to (a4) and (b1) to (b4),

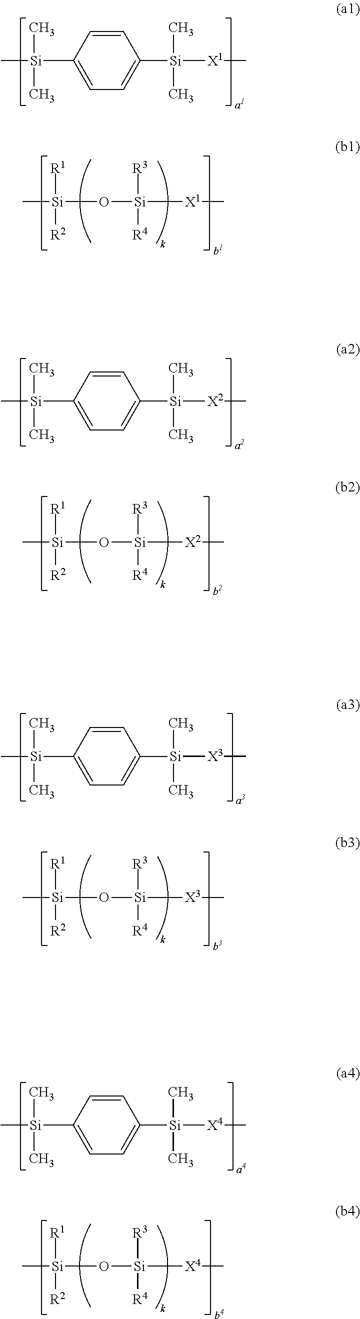

wherein R¹ to R⁴ each independently represent a hydrocarbyl group having 1 to 8 carbon atoms; “k” represents an integer of 1 to 600; a¹ to a⁴ and b¹ to b⁴ represent a composition ratio by mole of respective repeating units and represent numbers satisfying 0≤a¹<1, 0≤a²<1, 0≤a³<1, 0≤a⁴<1, 0≤b¹<1, 0≤b²<1, 0<b³<1, 0≤b⁴<1, 0<a¹+a²+a³<1, 0<b¹+b²+b³<1, and a¹+a²+a³+a⁴+b¹+b²+b³+b⁴=1; X¹ represents a divalent organic group represented by the following formula (X1); X² represents a divalent organic group represented by the following formula (X2); X³ represents a divalent organic group represented by the following formula (X3); and X⁴ represents a divalent organic group represented by the following formula (X4),

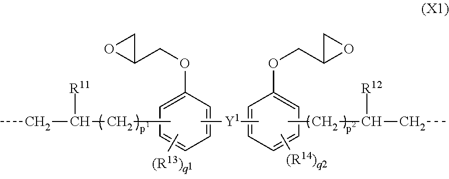

wherein Y¹ represents a single bond, a methylene group, a propane-2,2-diyl group, a 1,1,1,3,3,3-hexafluoropropane-2,2-diyl group, or a fluorene-9,9-diyl group; R¹¹ and R¹² each independently represent a hydrogen atom or a methyl group; R¹³ and R¹⁴ each independently represent a saturated hydrocarbyl group having 1 to 4 carbon atoms or a saturated hydrocarbyloxy group having 1 to 4 carbon atoms; p¹ and p² each independently represent an integer of 0 to 7; q¹ and q² each independently represent an integer of 0 to 2; and a dashed line represents a bond,

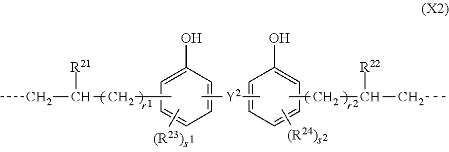

wherein Y² represents a single bond, a methylene group, a propane-2,2-diyl group, a 1,1,1,3,3,3-hexafluoropropane-2,2-diyl group, or a fluorene-9,9-diyl group; R²¹ and R²² each independently represent a hydrogen atom or a methyl group; R²³ and R²⁴ each independently represent a saturated hydrocarbyl group having 1 to 4 carbon atoms or a saturated hydrocarbyloxy group having 1 to 4 carbon atoms; r¹ and r² each independently represent an integer of 0 to 7; s¹ and s² each independently represent an integer of 0 to 2; and a dashed line represents a bond,

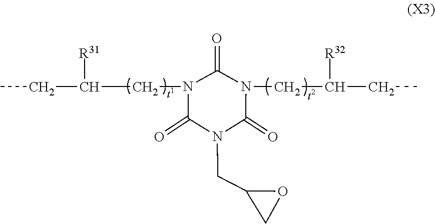

wherein R³¹ and R³² each independently represent a hydrogen atom or a methyl group; t¹ and t² each independently represent an integer of 0 to 7; and a dashed line represents a bond,

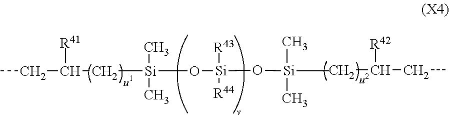

wherein R⁴¹ and R⁴² each independently represent a hydrogen atom or a methyl group; R⁴³ and R⁴⁴ each independently represent a hydrocarbyl group having 1 to 8 carbon atoms; u¹ and u² each independently represent an integer of 0 to 7; “v” represents an integer of 0 to 600; and a dashed line represents a bond.

[4]: The photosensitive resin composition according to any one of the above [1] to [3], further comprising (D) a crosslinker.

[5]: The photosensitive resin composition according to the above [4], wherein
(D) the crosslinker is at least one compound selected from the group consisting of: a nitrogen-containing compound selected from the group consisting of melamine compounds, guanamine compounds, glycoluril compounds and urea compounds, having 2 or more methylol and/or alkoxymethyl groups on average in one molecule; an amino condensate modified with formaldehyde or formaldehyde-alcohol; a phenol compound having 2 or more methylol or alkoxymethyl groups on average in one molecule; and an epoxy compound having two or more epoxy groups on average in one molecule.

[6]: The photosensitive resin composition according to any one of the above [1] to [5], further comprising (E) a solvent.

[7]: A photosensitive resin film obtained from the photosensitive resin composition according to any one of the above [1] to [6].

[8]: A photosensitive dry film comprising:
a support film; and
the photosensitive resin film according to the above [7] on the support film.

[9] A pattern-forming process comprising:
(i) forming a photosensitive resin film on a substrate using the photosensitive resin composition according to any one of the above [1] to [6];
(ii) exposing the photosensitive resin film; and
(iii) developing the exposed photosensitive resin film with a developer to form a pattern.

[10]: A pattern-forming process comprising:
(i′) forming a photosensitive resin film on a substrate by using the photosensitive dry film according to the above [8];
(ii) exposing the photosensitive resin film; and
(iii) developing the exposed photosensitive resin film with a developer to form a pattern.

[11]: The pattern-forming process according to the above [9], further comprising (iv) post-curing the photosensitive resin film patterned by the development at a temperature of 100° C. to 250° C.

[12]: The photosensitive resin composition according to any one of the above [1] to [6],
wherein the photosensitive resin composition is a material to form a film for protecting an electric and electronic part.

[13]: The photosensitive resin composition according to any one of the above [1] to [6],
wherein the photosensitive resin composition is a material to form a substrate-bonding film for bonding two substrates.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A photosensitive resin composition comprising:
(A) an acid-crosslinkable group-containing silicone resin;
(B) an oxazoline compound or a derivative thereof; and
(C) a photo-acid generator.

2. The photosensitive resin composition according to claim 1, wherein
(A) the silicone resin is represented by the following formula (A1), 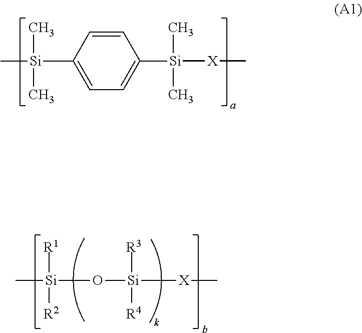
wherein R¹ to R⁴ each independently represent a hydrocarbyl group having 1 to 8 carbon atoms; “k” represents an integer of 1 to 600; “a” and “b” represent a composition ratio by mole of respective repeating units and represent numbers satisfying 0<a<1, 0<b<1, and a+b=1; and X represents a divalent organic group containing an epoxy group and/or a phenolic hydroxy group.

3. The photosensitive resin composition according to claim 2, wherein
(A) the silicone resin comprises repeating units represented by the following formulae (a1) to (a4) and (b1) to (b4), 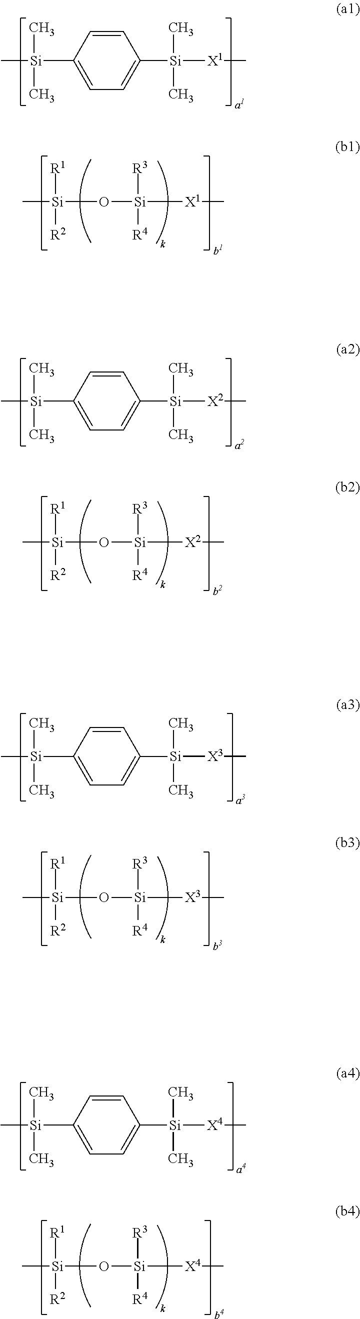
wherein R¹ to R⁴ each independently represent a hydrocarbyl group having 1 to 8 carbon atoms; “k” represents an integer of 1 to 600; a¹ to a⁴ and b¹ to b⁴ represent a composition ratio by mole of respective repeating units and represent numbers satisfying 0≤a¹<1, 0≤a²<1, 0≤a³<1, 0≤a⁴<1, 0≤b¹<1, 0≤b²<1, 0≤b³<1, 0≤b⁴<1, 0<a¹+a²+a³<1, 0<b¹+b²+b³<1, and a¹+a²+a³+a⁴+b¹+b²+b³+b⁴=1; X¹ represents a divalent organic group represented by the following formula (X1); X² represents a divalent organic group represented by the following formula (X2); X³ represents a divalent organic group represented by the following formula (X3); and X⁴ represents a divalent organic group represented by the following formula (X4), 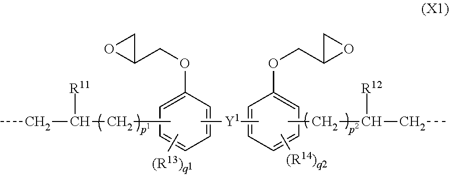
wherein Y¹ represents a single bond, a methylene group, a propane-2,2-diyl group, a 1,1,1,3,3,3-hexafluoropropane-2,2-diyl group, or a fluorene-9,9-diyl group; R¹¹ and R¹² each independently represent a hydrogen atom or a methyl group; R¹³ and R¹⁴ each independently represent a saturated hydrocarbyl group having 1 to 4 carbon atoms or a saturated hydrocarbyloxy group having 1 to 4 carbon atoms; p¹ and p² each independently represent an integer of 0 to 7; q¹ and q² each independently represent an integer of 0 to 2; and a dashed line represents a bond, 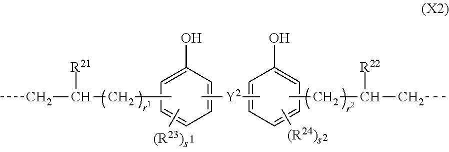
wherein Y² represents a single bond, a methylene group, a propane-2,2-diyl group, a 1,1,1,3,3,3-hexafluoropropane-2,2-diyl group, or a fluorene-9,9-diyl group; R²¹ and R²² each independently represent a hydrogen atom or a methyl group; R²³ and R²⁴ each independently represent a saturated hydrocarbyl group having 1 to 4 carbon atoms or a saturated hydrocarbyloxy group having 1 to 4 carbon atoms; r¹ and r² each independently represent an integer of 0 to 7; s¹ and s² each independently represent an integer of 0 to 2; and a dashed line represents a bond, 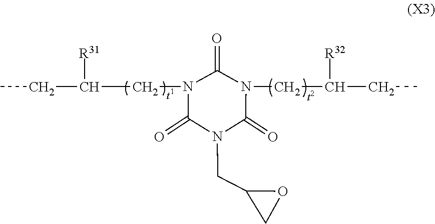
wherein R³¹ and R³² each independently represent a hydrogen atom or a methyl group; t¹ and t² each independently represent an integer of 0 to 7; and a dashed line represents a bond, 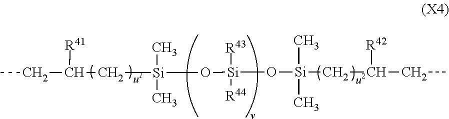
wherein R⁴¹ and R⁴² each independently represent a hydrogen atom or a methyl group; R⁴³ and R⁴⁴ each independently represent a hydrocarbyl group having 1 to 8 carbon atoms; u¹ and u² each independently represent an integer of 0 to 7; “v” represents an integer of 0 to 600; and a dashed line represents a bond.

4. The photosensitive resin composition according to claim 1, further comprising (D) a crosslinker.

5. The photosensitive resin composition according to claim 4, wherein
(D) the crosslinker is at least one compound selected from the group consisting of: a nitrogen-containing compound selected from the group consisting of melamine compounds, guanamine compounds, glycoluril compounds and urea compounds, having 2 or more methylol and/or alkoxymethyl groups on average in one molecule; an amino condensate modified with formaldehyde or formaldehyde-alcohol; a phenol compound having 2 or more methylol or alkoxymethyl groups on average in one molecule; and an epoxy compound having two or more epoxy groups on average in one molecule.

6. The photosensitive resin composition according to claim 1, further comprising (E) a solvent.

7. A photosensitive resin film obtained from the photosensitive resin composition according to claim 1.

8. A photosensitive dry film comprising:
a support film; and
the photosensitive resin film according to claim 7 on the support film.

9. A pattern-forming process comprising:
(i) forming a photosensitive resin film on a substrate using the photosensitive resin composition according to claim 1;
(ii) exposing the photosensitive resin film; and
(iii) developing the exposed photosensitive resin film with a developer to form a pattern.

10. A pattern-forming process comprising:
(i′) forming a photosensitive resin film on a substrate by using the photosensitive dry film according to claim 8;
(ii) exposing the photosensitive resin film; and
(iii) developing the exposed photosensitive resin film with a developer to form a pattern.

11. The pattern-forming process according to claim 9, further comprising (iv) post-curing the photosensitive resin film patterned by the development at a temperature of 100° C. to 250° C.

12. The photosensitive resin composition according to claim 1,
wherein the photosensitive resin composition is a material to form a film for protecting an electric and electronic part.

13. The photosensitive resin composition according to claim 1,
wherein the photosensitive resin composition is a material to form a substrate-bonding film for bonding two substrates.
